(19) United States
(12) Patent Application Publication
(10) Pub. No.: US 2025/0112175 A1
(43) Pub. Date: Apr. 3, 2025

(54) MICROELECTRONIC ASSEMBLIES WITH EDGE STRESS REDUCTION IN GLASS CORES

(71) Applicant: Intel Corporation, Santa Clara, CA (US)

(72) Inventors: Brandon C. Marin, Gilbert, AZ (US); Jesse C. Jones, Chandler, AZ (US); Yosef Kornbluth, Phoenix, AZ (US); Mitchell Page, Mesa, AZ (US); Soham Agarwal, Chandler, AZ (US); Fanyi Zhu, Gilbert, AZ (US); Shuren Qu, Gilbert, AZ (US); Hanyu Song, Chandler, AZ (US); Srinivas V. Pietambaram, Chandler, AZ (US); Yonggang Li, Chandler, AZ (US); Bai Nie, Chandler, AZ (US); Nicholas Haehn, Scottsdale, AZ (US); Astitva Tripathi, Mesa, AZ (US); Mohamed R. Saber, College Station, TX (US); Sheng Li, Gilbert, AZ (US); Pratyush Mishra, Tempe, AZ (US); Benjamin T. Duong, Phoenix, AZ (US); Kari Hernandez, Phoenix, AZ (US); Praveen Sreeramagiri, Gilbert, AZ (US); Yi Li, Chandler, AZ (US); Ibrahim El Khatib, Chandler, AZ (US); Whitney Bryks, Tempe, AZ (US); Mahdi Mohammadighaleni, Phoenix, AZ (US); Joshua Stacey, Chandler, AZ (US); Travis Palmer, San Diego, CA (US); Gang Duan, Chandler, AZ (US); Jeremy Ecton, Gilbert, AZ (US); Suddhasattwa Nad, Chandler, AZ (US); Haobo Chen, Chandler, AZ (US); Robin Shea McRee, Chandler, AZ (US); Mohammad Mamunur Rahman, Gilbert, AZ (US)

(73) Assignee: Intel Corporation, Santa Clara, CA (US)

(21) Appl. No.: 18/477,638

(22) Filed: Sep. 29, 2023

(51) Int. Cl. H01L 23/00; H01L 23/13; H01L 23/15; H01L 25/065

(52) U.S. Cl. CPC H01L 23/562; H01L 23/13; H01L 23/15; H01L 25/0655; H01L 24/14; H01L 24/16; H01L 24/32; H01L 24/73; H01L 2224/14177; H01L 2224/16145; H01L 2224/16227; H01L 2224/32225; H01L 2224/73204

(57) ABSTRACT

Various techniques for edge stress reduction in glass cores and related devices and methods are disclosed. In one example, a microelectronic assembly includes a glass core having a bottom surface, a top surface opposite the bottom surface, and one or more sidewalls extending between the bottom surface and the top surface, and further includes a panel of an organic material, wherein the glass core is embedded within the panel. In another example, a microelectronic assembly includes a glass core as in the first example, where an angle between a portion of an individual sidewall and one of the bottom surface or the top surface is greater than 90 degrees. In yet another example, a microelectronic assembly includes a glass core as in the first example, and further includes a pattern of a material on one of the one or more sidewalls.

### BACKGROUND

For the past several decades, scaling of features in integrated circuits (ICs) has been a driving force behind an ever-growing semiconductor industry and emerging applications in fields such as big data, artificial intelligence, mobile communications, and autonomous driving. Scaling to smaller and smaller features enables increased densities of functional units on the limited real estate of semiconductor chips. For example, shrinking transistor size allows incorporation of an increased number of memory or logic devices on a chip, lending to the fabrication of products with increased capacity. The drive for the ever-increasing capacity, however, is not without issue. The necessity to optimize fabrication and performance of each component (e.g., of each transistor) is becoming increasingly significant.

Parallel to optimizations at the transistor level, advanced IC packaging landscape is rapidly evolving to accommodate performance expectations and requirements of shrinking transistor size. Multiple IC dies are now commonly coupled together in a multi-die IC package to integrate features or functionality and to facilitate connections to other components, such as package substrates. For example, IC packages may include an embedded multi-die interconnect bridge (EMIB) for coupling two or more IC dies.

Integration of multiple dies in a single IC package has tremendous benefits but adds additional complexities due to placing materials with different material properties in close proximity to one another. When an IC package undergoes multiple processing steps involving various temperatures and pressure loads, individual materials within the package may behave differently from one another, resulting in out of plane deformation of various layers, known as “package warpage.” One way to address package warpage is to use stiffer cores to which different IC dies are attached. Recently, glass cores have been explored as alternatives to organic resin-based cores (e.g., cores based on using Ajinomoto Build-up Film (ABF)). Glass is considered more rigid than organic resin-based materials and has several advantages such as excellent thermal properties, low coefficient of thermal expansion (CTE), high electrical insulation, chemical resistance, optical transparency, and compatibility with advances semiconductor properties. However, a major challenge for widespread adoption of glass cores is the fact that glass is highly susceptible to damage due to mechanical or thermal stresses, or a combination of both.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a schematic side, cross-sectional view of one example microelectronic assembly, according to some embodiments of the present disclosure.

FIG. 2 is a schematic side, cross-sectional view of another example microelectronic assembly, according to some embodiments of the present disclosure.

FIG. 3 illustrates a singulation process that may cause edge stress in a glass core.

FIG. 4 illustrates various surfaces of a glass core from which damage may initiate, according to some embodiments of the present disclosure.

FIG. 5 illustrates a top-down perspective view of a glass core with angled sidewalls, according to some embodiments of the present disclosure.

FIGS. 6A-6E illustrate cross-sectional side views of glass cores with angled sidewalls, according to some embodiments of the present disclosure.

FIGS. 7A-7B illustrate top-down perspective views of glass cores with rounded or flattened corners, according to some embodiments of the present disclosure.

FIG. 8 illustrates a cross-sectional side view of a glass core with one or more patterns of a metallic material on at least portions of sidewalls, according to some embodiments of the present disclosure.

FIG. 9 illustrates a top-down perspective view of a glass core with one or more patterns of a metallic material on at least portions of sidewalls, according to some embodiments of the present disclosure.

FIGS. 10A-10C illustrate top-down views of example portions of a glass core sidewall with one or more patterns of a metallic material, according to some embodiments of the present disclosure.

FIGS. 11A-11I illustrate cross-sectional side views of glass cores with one or more patterns of a polymer material on at least portions of sidewalls, according to some embodiments of the present disclosure.

FIGS. 12A-12C illustrate perspective views of glass cores with one or more patterns of a polymer material on at least portions of sidewalls, according to some embodiments of the present disclosure.

FIGS. 13A-13C illustrate perspective views of glass cores embedded in organic panels, according to some embodiments of the present disclosure.

FIGS. 14A-14C illustrate top-down views of example glass core units with one or more glass cores embedded in organic panels, according to some embodiments of the present disclosure.

FIG. 15 is a top view of a wafer and dies that may be included in a microelectronic assembly with a glass core in accordance with any of the embodiments disclosed herein, according to some embodiments of the present disclosure.

FIG. 16 is a side, cross-sectional view of an IC device that may be included in a microelectronic assembly with a glass core in accordance with any of the embodiments disclosed herein, according to some embodiments of the present disclosure.

FIG. 17 is a side, cross-sectional view of an IC device assembly that may include a glass core in accordance with any of the embodiments disclosed herein, according to some embodiments of the present disclosure.

FIG. 18 is a block diagram of an example communication device that may include a microelectronic assembly with a glass core in accordance with any of the embodiments disclosed herein, according to some embodiments of the present disclosure.

### DETAILED DESCRIPTION

Various techniques for edge stress reduction in glass cores and related devices and methods are disclosed herein. In the following, a glass core to which one or more techniques for edge stress reduction as described herein have been applied is referred to as a “glass core with edge stress reduction.” In one example, a microelectronic assembly includes a glass core having a bottom surface, a top surface opposite the bottom surface, and one or more sidewalls extending between the bottom surface and the top surface, and further includes a panel of an organic material, wherein the glass core is embedded within the panel. In another example, a microelectronic assembly includes a glass core as in the first example, where an angle between a portion of an individual sidewall and one of the bottom surface or the top surface is greater than 90 degrees. In yet another example, a microelectronic assembly includes a glass core as in the first example, and further includes a pattern of a material on one of the one or more sidewalls.

Integration of layers of different materials (e.g., multiple dies, redistribution layers, package substrates) in a single IC package or a microelectronic assembly is challenging due to package warpage, among others. Providing IC packages or microelectronic assemblies with glass cores to which one or more techniques for edge stress reduction as described herein have been applied may help. Various ones of the embodiments disclosed herein may help achieve reliable integration of multiple layers of different materials within a single microelectronic assembly at a lower cost and/or with greater design flexibility, relative to conventional approaches. Various ones of the microelectronic assemblies disclosed herein may exhibit reduced warpage, relative to conventional approaches. The microelectronic assemblies disclosed herein may be particularly advantageous for small and low-profile applications in computers, tablets, industrial robots, and consumer electronics (e.g., wearable devices).

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

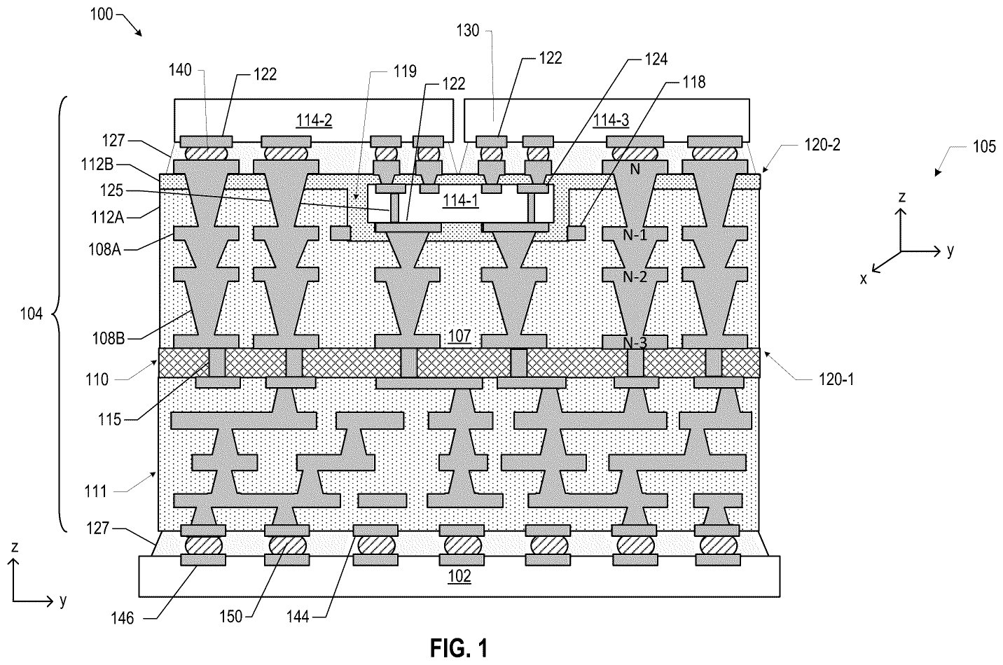

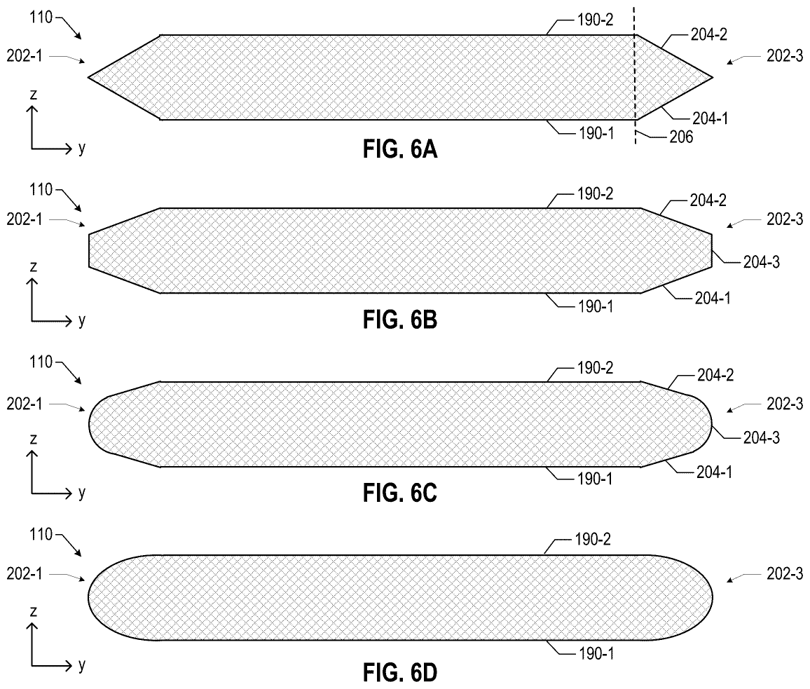

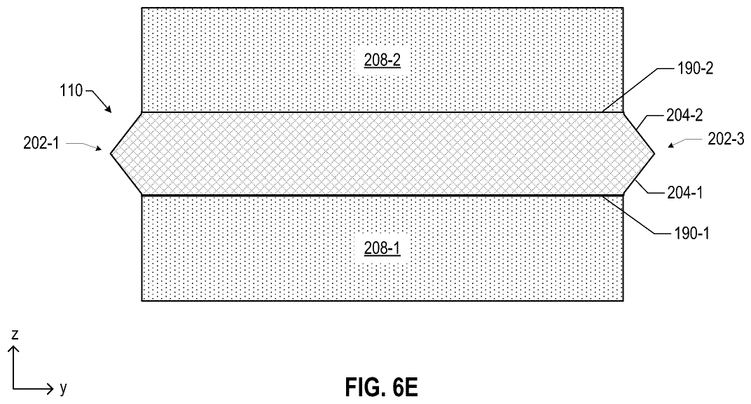

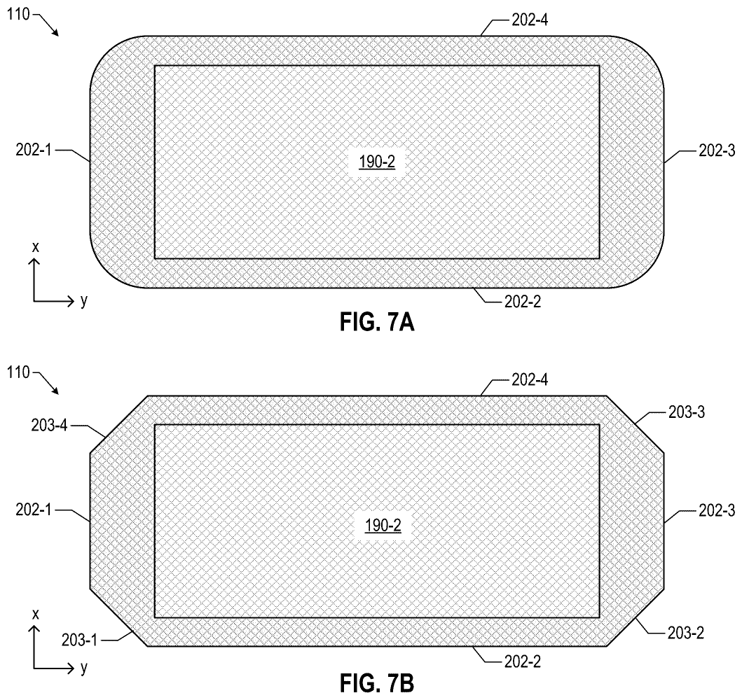

Any of the features discussed with reference to any of accompanying drawings herein may be combined with any other features to form a microelectronic assembly 100, a glass core 110, or a communication device 1800, as appropriate. For convenience, the phrase “dies 114” may be used to refer to a collection of dies 114-1, 114-2, and so on, etc. A collection of drawings labeled with different letters may be referred to without the letters, e.g., a collection of FIGS. 6A-6E may be referred to as “FIG. 6,” a collection of FIGS. 7A-7B may be referred to as “FIG. 7,” etc. A number of elements of the drawings with same reference numerals may be shared between different drawings; for ease of discussion, a description of these elements provided with respect to one of the drawings is not repeated for the other drawings, and these elements may take the form of any of the embodiments disclosed herein. To not clutter the drawings, if multiple instances of certain elements are illustrated, only some of the elements may be labeled with a reference numeral (e.g., a plurality of conductive contacts 122 are shown in FIG. 1 but only one of the them is labeled with a reference numeral). Also to not clutter the drawings, not all reference numerals shown in one of the drawings are shown in other similar drawings. The drawings are not necessarily to scale. Although many of the drawings illustrate rectilinear structures with flat walls and right-angle corners, this is simply for ease of illustration and may not reflect real-life process limitations which may cause various features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers. There may be other defects not listed here but that are common within the field of semiconductor device fabrication and packaging. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of a glass core with edge stress reduction as described herein.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10%, e.g., within +/−5% or within +/−2%, of the exact orientation.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, the terms “package” and “IC package” are synonymous, as are the terms “die” and “IC die.” Furthermore, the terms “chip,” “chiplet,” “die,” and “IC die” may be used interchangeably herein.

Although certain elements may be referred to in the singular herein, such elements may include multiple sub-elements. For example, “a dielectric material” may include one or more dielectric materials or “an insulator material” may include one or more insulator materials. The terms “oxide,” “carbide,” “nitride,” etc. refer to compounds containing, respectively, oxygen, carbon, nitrogen, etc. The term “high-k dielectric” refers to a material having a higher dielectric constant than silicon oxide, while the term “low-k dielectric” refers to a material having a lower dielectric constant than silicon oxide. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. With reference to optical signals and/or devices, components and elements that operate on or using optical signals, the term “conducting” can also mean “optically conducting.” The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

FIG. 1 is a schematic side, cross-sectional view of one example microelectronic assembly 100 in which a glass core with edge stress reduction as described herein may be implemented, according to some embodiments of the present disclosure. The microelectronic assembly 100 may include a substrate 107 with a double-sided bridge die 114-1 in a cavity 119 in the substrate 107, the die 114-1 may be electrically coupled to a conductive via 108B or a conductive trace 108A in a metal layer N−1 of the substrate 107 that is beneath a bottom of the cavity 119. The substrate 107 may include a dielectric material 112 (e.g., a first dielectric material layer 112A and a second dielectric material layer 112B, as shown) and a conductive material 108 (e.g., lines/traces/pads/contacts 108A and vias 108B, as shown), with the conductive material 108 arranged in the dielectric material 112 to provide conductive pathways through the substrate 107. The substrate 107 may include a first surface 120-1 and an opposing second surface 120-2. The die 114-1 may be surrounded by a dielectric material 112 of the substrate 107. The die 114-1 may include a bottom surface (e.g., the surface facing towards the first surface 120-1) with first conductive contacts 122, an opposing top surface (e.g., the surface facing towards the second surface 120-2) with second conductive contacts 124, and TSVs 125 coupling respective first and second conductive contacts 122, 124. In some embodiments, a pitch of the first conductive contacts 122 on the first die 114-1 maybe between 25 microns and 250 microns. As used herein, pitch is measured center-to-center (e.g., from a center of a conductive contact to a center of an adjacent conductive contact). In some embodiments, a pitch of the second conductive contacts 124 on the first die 114-1 maybe between 25 microns and 100 microns. The dies 114-2, 114-3 may include a set of conductive contacts 122 on the bottom surface of the die (e.g., the surface facing towards the first surface 120-1). The die 114 may include other conductive pathways (e.g., including lines and vias) and/or to other circuitry (not shown) coupled to the respective conductive contacts (e.g., conductive contacts 122, 124) on the surface of the die 114. As used herein, the terms “die,” “microelectronic component,” and similar variations may be used interchangeably. As used herein, the terms “interconnect component,” “bridge die,” and similar variations may be used interchangeably. The bridge die 114-1 may be electrically coupled to dies 114-2, 114-3 by die-to-die (DTD) interconnects 130 at a second surface 120-2. In particular, conductive contacts 124 on a top surface of the die 114-1 may be coupled to conductive contacts 122 on a bottom surface of dies 114-2, 114-3 by conductive vias 108B through the dielectric material 112B.

As used herein, a “conductive contact” may refer to a portion of conductive material (e.g., metal) serving as an electrical interface between different components (e.g., part of a conductive interconnect); conductive contacts may be recessed in, flush with, or extending away (e.g., having a pillar shape) from a surface of a component, and may take any suitable form (e.g., a conductive pad or socket, or portion of a conductive line or via). In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

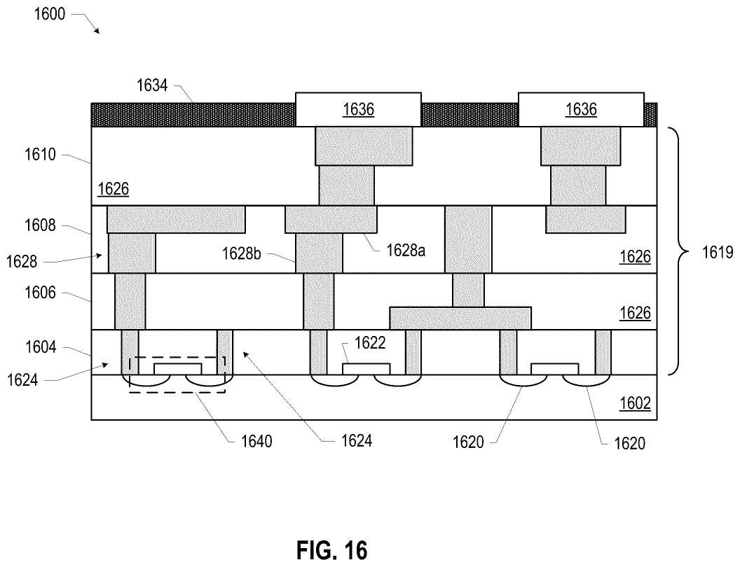

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 16. The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked).

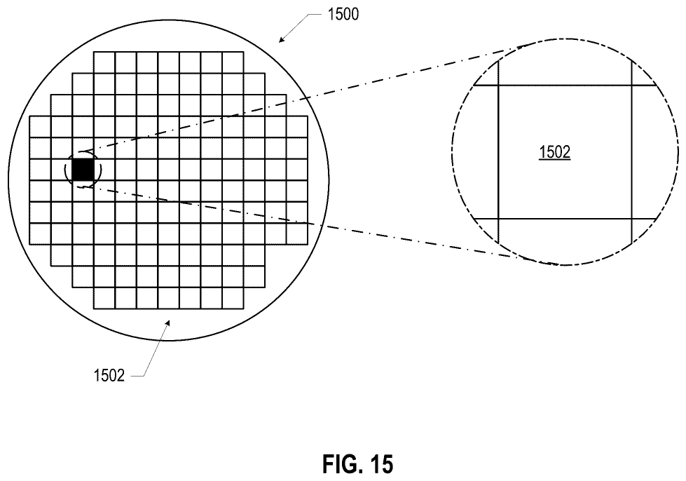

In some embodiments, the die 114 may include conductive pathways to route power, ground, and/or signals to/from other dies 114 included in the microelectronic assembly 100. For example, the die 114-1 may include TSVs 125, including a conductive material via, such as a metal via, isolated from the surrounding silicon or other semiconductor material by a barrier oxide), or other conductive pathways through which power, ground, and/or signals may be transmitted between the package substrate 102 and one or more dies 114 “on top” of the die 114-1 (e.g., in the embodiment of FIG. 1, the dies 114-2 and/or 114-3). In some embodiments, the die 114-1 may not route power and/or ground to the dies 114-2 and 114-3; instead, the dies 114-2, 114-3 may couple directly to power and/or ground lines in the package substrate 102 by substrate-to-package substrate (STPS) interconnects 150, conductive pathways 108 in the substrate 107, and die-to-substrate (DTS) interconnects 140. In some embodiments, the die 114-1 may be thicker than the dies 114-2, 114-3. In some embodiments, the die 114-1 may be a memory device or a high frequency serializer and deserializer (SerDes), such as a Peripheral Component Interconnect (PCI) express. In some embodiments, the die 114-1 may be a processing die, a radio frequency chip, a power converter, a network processor, a workload accelerator, a voltage regulator die, or a security encryptor. In some embodiments, the die 114-2 and/or the die 114-3 may be a processing die, a radio frequency chip, a power converter, a network processor, a workload accelerator, a voltage regulator die, or a security encryptor. In some embodiments, the die 114 may be as described below with reference to the die 1502 of FIG. 15.

The dielectric material 112 of the substrate 107 may be formed in layers (e.g., at least a first dielectric material layer 112A and a second dielectric material layer 112B). In some embodiments, the dielectric material 112 may include an organic material, such as an organic build-up film. In some embodiments, the dielectric material 112 may include a ceramic, an epoxy film having filler particles therein, glass, an inorganic material, or combinations of organic and inorganic materials, for example. In some embodiments, the conductive material 108 may include a metal (e.g., copper). In some embodiments, the substrate 107 may include layers of dielectric material 112/conductive material 108, with lines/traces/pads/contacts (e.g., 108A) of conductive material 108 in one layer electrically coupled to lines/traces/pads/contacts (e.g., 108A) of conductive material 108 in an adjacent layer by vias (e.g., 108B) of the conductive material 108 extending through the dielectric material 112. Conductive elements 108A may be referred to herein as “conductive lines,” “conductive traces,” “conductive pads,” or “conductive contacts.” A substrate 107 including such layers may be formed using a printed circuit board (PCB) fabrication technique, for example.

An individual layer of dielectric material 112 (e.g., a first dielectric material layer 112A) may include a cavity 119 and the bridge die 114-1 may be at least partially nested in the cavity 119. The bridge die 114-1 may be surrounded by (e.g., embedded in) a next individual layer of dielectric material 112 (e.g., a second dielectric material layer 112B). In some embodiments, a cavity 119 is tapered, narrowing towards a bottom surface of the cavity 119 (e.g., the surface towards the first surface 120-1 of the substrate 107). A cavity 119 may be indicated by a seam between the dielectric material 112A and the dielectric material 112B. As shown in FIG. 1, in cases where the bridge die 114-1 is partially nested in a cavity 119, a top surface of the bridge die 114-1 may extend above a top surface of dielectric material 112A. In cases where the bridge die 114-1 is fully nested in a cavity 119 (not shown), a top surface of the bridge die 114-1 may be planar with or below a top surface of dielectric material 112A.

A substrate 107 may include N layers of conductive material 108, where N is an integer greater than or equal to one. In FIG. 1, the layers are labeled in descending order from the second surface 120-2 of the substrate 107 (e.g., layer N, layer N−1, layer N−2, etc.). In particular, as shown in FIG. 1, a substrate 107 may include four metal layers (e.g., N, N−1, N−2, and N−3). The N metal layer may include conductive contacts 108A at a top surface 120-2 of the substrate 107 that are coupled to conductive contacts 122 at bottom surfaces of the die 114-2, 114-3 by DTS interconnects 140. The N−2 metal layer may include conductive traces 108A having a top surface (e.g., the surface facing towards the second surface 120-2 of the substrate 107), an opposing bottom surface (e.g., the surface facing towards the first surface 120-1 of the substrate 107), and lateral surfaces extending between the top and bottom surfaces of the conductive traces 108A. A substrate 107 may further include an N−1 metal layer above the N−2 metal layer and below the N metal layer, where a portion of the N−1 metal layer includes a metal ring 118 exposed at a perimeter of the bottom of the cavity 119. The metal ring 118 may be coplanar with the conductive traces 108A of the N−1 metal layer and may be proximate to the edges of the cavity 119, as shown.

Although a particular number and arrangement of layers of dielectric material 112/conductive material 108 are shown in various ones of the accompanying figures, these particular numbers and arrangements are simply illustrative, and any desired number and arrangement of dielectric material 112/conductive material 108 may be used. Further, although a particular number of layers are shown in the substrate 107 (e.g., four layers), these layers may represent only a portion of the substrate 107, for example, further layers may be present (e.g., layers N−4, N−5, N−6, etc.).

As shown in FIG. 1, the substrate 107 may further include a glass core 110 with through core vias 115 and further layers 111 may be present below the glass core 110 and coupled to a package substrate 102 by interconnects 150. As used herein, the term “glass core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass core 110 may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, the glass core 110 may be an amorphous solid glass layer. In some embodiments, the glass core 110 may include silicon and oxygen, as well as any one or more of aluminum, boron, magnesium, calcium, barium, tin, sodium, potassium, strontium, phosphorus, zirconium, lithium, titanium, and zinc. In some embodiments, the glass core 110 may include a material, e.g., any of the materials described above, with a weight percentage of silicon being at least about 0.5%, e.g., between about 0.5% and 50%, between about 1% and 48%, or at least about 23%. For example, if the glass core 110 is fused silica, the weight percentage of silicon may be about 47%. In some embodiments, the glass core 110 may include at least 23% silicon and/or at least 26% oxygen by weight, and, in some further embodiments, the glass core 110 may further include at least 5% aluminum by weight. In some embodiments, the glass core 110 may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the glass core 110 may be a layer of glass that does not include an organic adhesive or an organic material. The glass core 110 may be distinguished from, for example, the “prepreg” or “RF4” core of a PCB substrate which typically includes glass fibers embedded in a resinous organic material such as an epoxy. In some embodiments, a cross-section of the glass core 110 in an x-z plane, a y-z plane, and/or an x-y plane of an example coordinate system 105, shown in FIG. 1, may be substantially rectangular.

Together, the substrate 107, including the glass core 110, and the dies 114 may be referred to as a “a multi-layer die subassembly 104.” The glass core 110 may provide mechanical stability to the multi-layer die subassembly 104, the substrate 107, and/or the microelectronic assembly 100. The glass core 110 may reduce warpage and may provide a more robust surface for attachment of the multi-layer die subassembly 104 to a package substrate 102 or other substrate (e.g., an interposer or a circuit board).

The substrate 107 (e.g., further layers 111) may be coupled to a package substrate 102 by STPS interconnects 150. In particular, the top surface of the package substrate 102 may include a set of conductive contacts 146. Conductive contacts 144 on the bottom surface of the substrate 107 may be electrically and mechanically coupled to the conductive contacts 146 on the top surface of the package substrate 102 by the STPS interconnects 150. The package substrate 102 may include an insulating material (e.g., a dielectric material formed in multiple layers, as known in the art) and one or more conductive pathways to route power, ground, and signals through the dielectric material (e.g., including conductive traces and/or conductive vias, as shown). In some embodiments, the insulating material of the package substrate 102 may be a dielectric material, such as an organic dielectric material, a fire retardant grade 4 material (FR-4), bismaleimide triazine (BT) resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the package substrate 102 is formed using standard PCB processes, the package substrate 102 may include FR-4, and the conductive pathways in the package substrate 102 may be formed by patterned sheets of copper separated by build-up layers of the FR-4. The conductive pathways in the package substrate 102 may be bordered by liner materials, such as adhesion liners and/or barrier liners, as suitable. In some embodiments, the package substrate 102 may be formed using a lithographically defined via packaging process. In some embodiments, the package substrate 102 may be manufactured using standard organic package manufacturing processes, and thus the package substrate 102 may take the form of an organic package. In some embodiments, the package substrate 102 may be a set of redistribution layers formed on a panel carrier by laminating or spinning on a dielectric material, and creating conductive vias and lines by laser drilling and plating. In some embodiments, the package substrate 102 may be formed on a removable carrier using any suitable technique, such as a redistribution layer technique. Any method known in the art for fabrication of the package substrate 102 may be used, and for the sake of brevity, such methods will not be discussed in further detail herein.

In some embodiments, the package substrate 102 may be a lower density medium and the die 114 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual-damascene process. In some embodiments, additional dies may be disposed on the top surface of the dies 114-2, 114-3. In some embodiments, additional components may be disposed on the top surface of the dies 114-2, 114-3. Additional passive components, such as surface-mount resistors, capacitors, and/or inductors, may be disposed on the top surface or the bottom surface of the package substrate 102, or embedded in the package substrate 102.

The microelectronic assembly 100 of FIG. 1 may also include an underfill material 127. In some embodiments, the underfill material 127 may extend between the substrate 107 and the package substrate 102 around the associated STPS interconnects 150. In some embodiments, the underfill material 127 may extend between different ones of the top level dies 114-2, 114-3 and the top surface of the substrate 107 around the associated DTS interconnects 140 and between the bridge die 114-1 and the top level dies 114-2, 114-3 around the DTD interconnects 130. The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering the multi-layer die subassembly 104 to the package substrate 102 when forming the STPS interconnects 150, and then polymerizes and encapsulates the STPS interconnects 150. The underfill material 127 may be selected to have a CTE that may mitigate or minimize the stress between the substrate 107 and the package substrate 102 arising from uneven thermal expansion in the microelectronic assembly 100. In some embodiments, the CTE of the underfill material 127 may have a value that is intermediate to the CTE of the package substrate 102 (e.g., the CTE of the dielectric material of the package substrate 102) and a CTE of the dies 114 and/or dielectric material 112 of the substrate 107.

The STPS interconnects 150 disclosed herein may take any suitable form. In some embodiments, a set of STPS interconnects 150 may include solder (e.g., solder bumps or balls that are subject to a thermal reflow to form the STPS interconnects 150), for example, as shown in FIG. 1, the STPS interconnects 150 may include solder between a conductive contacts 144 on a bottom surface of the substrate 107 and a conductive contact 146 on a top surface of the package substrate 102. In some embodiments, a set of STPS interconnects 150 may include an anisotropic conductive material, such as an anisotropic conductive film or an anisotropic conductive paste. An anisotropic conductive material may include conductive materials dispersed in a non-conductive material.

The DTD interconnects 130 disclosed herein may take any suitable form. The DTD interconnects 130 may have a finer pitch than the STPS interconnects 150 in a microelectronic assembly. In some embodiments, the dies 114 on either side of a set of DTD interconnects 130 may be unpackaged dies, and/or the DTD interconnects 130 may include small conductive bumps (e.g., copper bumps). The DTD interconnects 130 may have too fine a pitch to couple to the package substrate 102 directly (e.g., too fine to serve as DTS interconnects 140 or STPS interconnects 150). In some embodiments, a set of DTD interconnects 130 may include solder. In some embodiments, a set of DTD interconnects 130 may include an anisotropic conductive material, such as any of the materials discussed above. In some embodiments, the DTD interconnects 130 may be used as data transfer lanes, while the STPS interconnects 150 may be used for power and ground lines, among others. In some embodiments, some or all of the DTD interconnects 130 in a microelectronic assembly 100 may be metal-to-metal interconnects (e.g., copper-to-copper interconnects, or plated interconnects). In such embodiments, the DTD interconnect 130 may be bonded together (e.g., under elevated pressure and/or temperature) without the use of intervening solder or an anisotropic conductive material. Any of the conductive contacts disclosed herein (e.g., the conductive contacts 122, 124, 144, and/or 146) may include bond pads, solder bumps, conductive posts, or any other suitable conductive contact, for example. In some embodiments, some or all of the DTD interconnects 130 and/or the DTS interconnects 140 in a microelectronic assembly 100 may be solder interconnects that include a solder with a higher melting point than a solder included in some or all of the STPS interconnects 150. For example, when the DTD interconnects 130 and the DTS interconnects 140 in a microelectronic assembly 100 are formed before the STPS interconnects 150 are formed, solder-based DTD interconnects 130 and DTS interconnects 140 may use a higher-temperature solder (e.g., with a melting point above 200 degrees Celsius), while the STPS interconnects 150 may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

In the microelectronic assemblies 100 disclosed herein, some or all of the DTS interconnects 140 and the STPS interconnects 150 may have a larger pitch than some or all of the DTD interconnects 130. DTD interconnects 130 may have a smaller pitch than STPS interconnects 150 due to the greater similarity of materials in the different dies 114 on either side of a set of DTD interconnects 130 than between the substrate 107 and the top level dies 114-2, 114-3 on either side of a set of DTS interconnects 140, and between the substrate 107 and the package substrate 102 on either side of a set of STPS interconnects 150. In particular, the differences in the material composition of a substrate 107 and a die 114 or a package substrate 102 may result in differential expansion and contraction due to heat generated during operation (as well as the heat applied during various manufacturing operations). To mitigate damage caused by this differential expansion and contraction (e.g., cracking, solder bridging, etc.), the DTS interconnects 140 and the STPS interconnects 150 may be formed larger and farther apart than DTD interconnects 130, which may experience less thermal stress due to the greater material similarity of the pair of dies 114 on either side of the DTD interconnects. In some embodiments, the DTS interconnects 140 disclosed herein may have a pitch between 25 microns and 250 microns. In some embodiments, the STPS interconnects 150 disclosed herein may have a pitch between 55 microns and 1000 microns, while the DTD interconnects 130 disclosed herein may have a pitch between 25 microns and 100 microns.

The microelectronic assembly 100 of FIG. 1 may also include a circuit board (not shown). The package substrate 102 may be coupled to the circuit board by second-level interconnects at the bottom surface of the package substrate 102. The second-level interconnects may be any suitable second-level interconnects, including solder balls for a ball grid array arrangement, pins in a pin grid array arrangement or lands in a land grid array arrangement. The circuit board may be a motherboard, for example, and may have other components attached to it. The circuit board may include conductive pathways and other conductive contacts for routing power, ground, and signals through the circuit board, as known in the art. In some embodiments, the second-level interconnects may not couple the package substrate 102 to a circuit board, but may instead couple the package substrate 102 to another IC package, an interposer, or any other suitable component. In some embodiments, the substrate 107 may not be coupled to a package substrate 102, but may instead be coupled to a circuit board, such as a PCB.

Although FIG. 1 depicts a microelectronic assembly 100 having a substrate with a particular number of dies 114 and conductive pathways 108 coupled to other dies 114, this number and arrangement are simply illustrative, and a microelectronic assembly 100 may include any desired number and arrangement of dies 114. Although FIG. 1 shows the die 114-1 as a double-sided die and the dies 114-2, 114-3 as single-sided dies, the dies 114-2, 114-3 may be double-sided dies and the dies 114 may be a single-pitch die or a mixed-pitch die. In some embodiments, additional components may be disposed on the top surface of the dies 114-2 and/or 114-3. In this context, a double-sided die refers to a die that has connections on both surfaces. In some embodiments, a double-sided die may include through TSVs to form connections on both surfaces. The active surface of a double-sided die, which is the surface containing one or more active devices and a majority of interconnects, may face either direction depending on the design and electrical requirements.

Many of the elements of the microelectronic assembly 100 of FIG. 1 are included in other ones of the accompanying drawings; the discussion of these elements is not repeated when discussing these drawings, and any of these elements may take any of the forms disclosed herein. Further, a number of elements are illustrated in FIG. 1 as included in the microelectronic assembly 100, but a number of these elements may not be present in a microelectronic assembly 100. For example, in various embodiments, the further layers 111, the underfill material 127, and the package substrate 102 may not be included. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

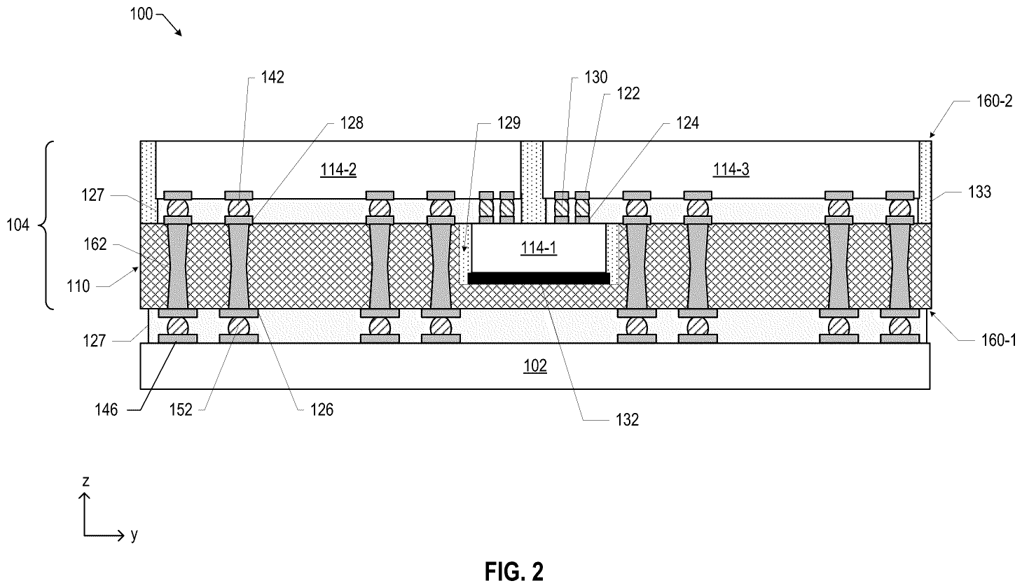

FIG. 2 is a schematic cross-sectional view of another example microelectronic assembly 100 according to some embodiments of the present disclosure. The configuration of the embodiment shown in the figure is like that of FIG. 1, except for differences as described further. Instead of including the glass core 110 as a part of the substrate 107, as was shown in FIG. 1, the microelectronic assembly 100 of FIG. 2 includes a glass core 110 on its own, where one or more dies 114 may be coupled to the glass core 110. In FIG. 2, the multi-layer die subassembly 104 includes the glass core 110 and the plurality of dies 114 as described above. The multi-layer die subassembly 104 may have a first surface 160-1 and an opposing second surface 160-2. The glass core 110 may provide mechanical stability to the multi-layer die subassembly 104 and/or the microelectronic assembly 100 of FIG. 2, may reduce warpage, and may provide a more robust surface for attachment of the multi-layer die subassembly 104 to a package substrate 102 or other substrate (e.g., an interposer or a circuit board).

The glass core 110 may include a cavity 129 with an opening facing the second surface 160-2 and the die 114-1 may be nested, fully or at least partially, in the cavity 129. As shown in FIG. 2, in cases where the die 114-1 is fully nested in a cavity 129, a top surface of the die 114-1 may be planar with or below a top surface of the glass core 110. In cases where the die 114-1 is partially nested in a cavity 129 (not shown), a top surface of the die 114-1 may extend above a top surface of the glass core 110. The cavity 129 may be at least partially filled with a dielectric material 112A or 112B, described above. The die 114-1 may be attached to a bottom surface of the cavity 129 by a die-attach film (DAF) 132. A DAF 132 may be any suitable material, including a non-conductive adhesive, die-attach film, a B-stage underfill, or a polymer film with adhesive property. A DAF 132 may have any suitable dimensions, for example, in some embodiments, a DAF 132 may have a thickness (e.g., height or z-height) between 5 microns and 10 microns.

The die 114-1 may be coupled to the dies 114-2, 114-3 in a layer above the die 114-1 through the DTD interconnects 130. The DTD interconnects 130 may be disposed between some of the conductive contacts 122 at the bottom of the dies 114-2, 114-3 and some of the conductive contacts 124 at the top of the die 114-1. Some other conductive contacts 122 at the bottom of the dies 114-2 and/or 114-3 may further couple one or more of the dies 114-2, 114-3 to the glass core 110 by glass core-to-die (GCTD) interconnects 142. The GCTD interconnects 142 may be disposed between some of the conductive contacts 122 at the bottom of the dies 114-2, 114-3 and some of the conductive contacts 128 at the top of the glass core 110. The GCTD interconnects 142 may be similar to the DTS interconnects 140, described above. In some embodiments, the underfill material 127 may extend between different ones of the dies 114 around the associated DTD interconnects 130 and/or GCTD interconnects 142. In some embodiments, a die 114-2 and/or a die 114-3 may be embedded in an insulating material 133. In some embodiments, an overall thickness (e.g., a z-height) of the insulating material 133 may be between 200 microns and 800 microns (e.g., substantially equal to a thickness of die 114-2 or 114-3 and the underfill material 127). In some embodiments, the insulating material 133 may form multiple layers (e.g., a dielectric material formed in multiple layers, as known in the art) and may embed one or more dies 114 in a layer. In some embodiments, the insulating material 133 may be a dielectric material, such as an organic dielectric material, a fire retardant grade 4 material (FR-4), BT resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics). In some embodiments, the insulating material 133 may be a mold material, such as an organic polymer with inorganic silica particles.

As shown in FIG. 2, the glass core 110 may further include conductive contacts 126 at the bottom of the glass core 110, and through-glass vias (TGVs) 162 may extend between and electrically couple conductive contacts 126 at the bottom of the glass core 110 and conductive contacts 128 at the top of the glass core 110. The conductive contacts 126, 128 may be similar to other conductive contacts disclosed herein (e.g., the conductive contacts 122, 124, 144, and/or 146), and may include bond pads, solder bumps, conductive posts, or any other suitable conductive contact, for example. The TGVs 162 may be formed of any appropriate conductive material, such as copper, silver, nickel, gold, aluminum, or other metals or alloys, for example. The TGVs 162 may be formed using any suitable process, including, for example, a direct laser drilling or laser induced deep etching process. In some embodiments, the TGVs 162 disclosed herein may have a pitch between 50 microns and 500 microns, e.g., as measured from a center of one TGV 162 to a center of an adjacent TGV 162. The TGVs 162 may have any suitable size and shape. In some embodiments, the TGVs 162 may have a circular, rectangular, or other shaped cross-section. In some embodiments, the TGVs 162 may have a thickness (e.g., z-height) between 50 microns and 1,000 microns. In some embodiments, at least some of the TGVs 162 may be an hourglass shape as shown in FIG. 2. For example, at least some of the TGVs 162 may has a first width at the first face of the glass core 110 (e.g., at the bottom face of the glass core 110), a second width at the second face of the glass core 110 (e.g., at the top face of the glass core 110), and a third width between the first face and the second face of the glass core 110, where the third width is smaller than the first width and the second width. In some embodiments, at least some of the TGVs 162 may taper down from one face of the glass core 110 to another, e.g., from the top face of the glass core 110 to the bottom face of the glass core 110.

The dies 114-2, 114-3 may be electrically coupled to the package substrate 102 through the TGVs 162 and glass core-to-package substrate (GCTPS) interconnects 152, which may be power delivery interconnects or high-speed signal interconnects. The GCTPS interconnects 152 may be similar to the STPS interconnects 150, described above. The top surface of the package substrate 102 may include a set of conductive contacts 146, the multi-layer die subassembly 104 may include a set of conductive contacts 126 on the bottom surface 160-1, and the GCTPS interconnects 152 may be between, and couple the conductive contacts 146 with corresponding ones of the conductive contacts 126. In some embodiments, the underfill material 127 may extend between the glass core 110 and the package substrate 102 around the associated GCTPS interconnects 152.

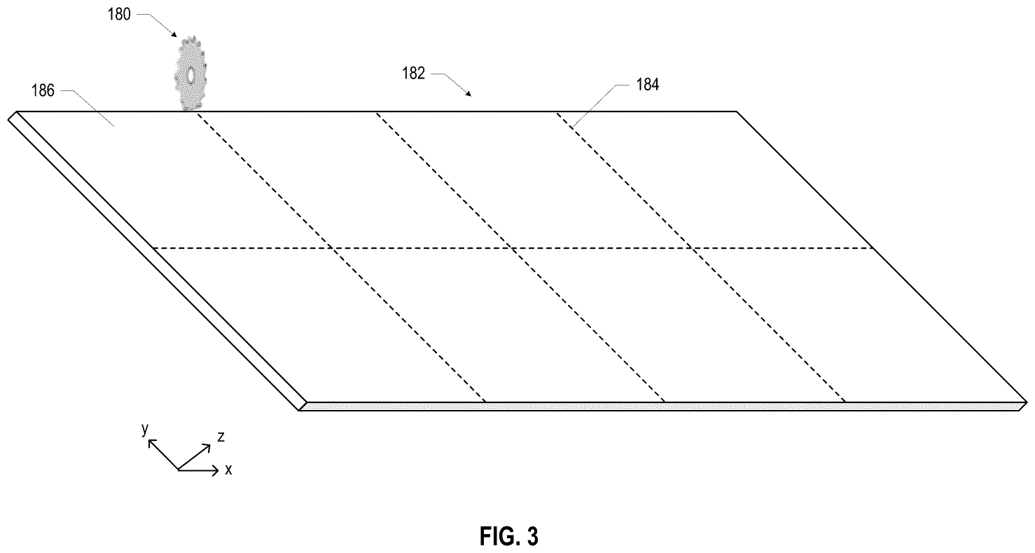

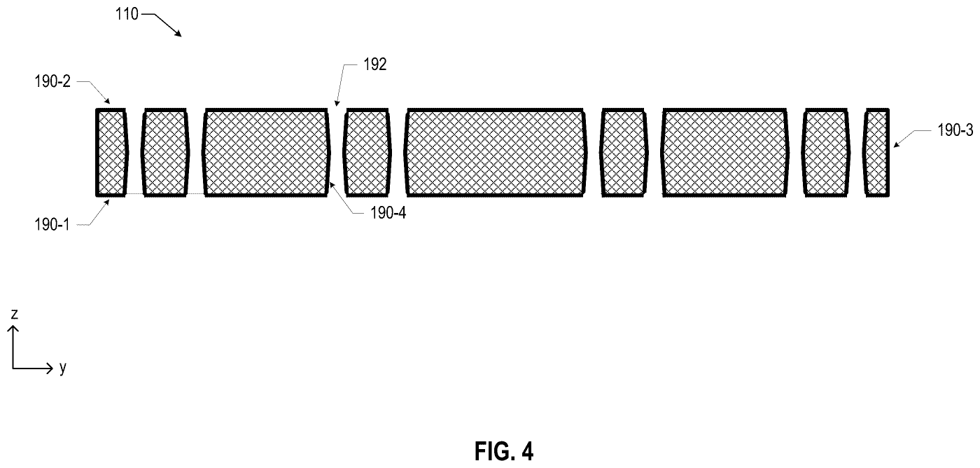

The glass core 110 included in a microelectronic assembly 100 as described with reference to FIG. 1 or FIG. 2, may be subject to edge stress prior to inclusion in the microelectronic assembly 100. For example, FIG. 3 illustrates a singulation process that may cause edge stress in and, consequently, damage, a glass core 110. As shown in FIG. 3, during singulation process, a cutting tool 180 (e.g., a glass cutter, a diamond blade, or a saw) may be used to cut a larger block 182 of glass core along lines 184, to separate the larger block 182 into individual units 186. Individual units 186 may then serve as glass cores 110, described herein. However, as a result of cutting, the surfaces of the individual units 186 along the lines 184 (e.g., edges of the individual units 186) may be subject to edge stress and, as a result, damaged in that they may high surface roughness, be jagged or be otherwise uneven. One or more techniques for edge stress reduction as described herein may then be applied to the individual units 186 either before or after the singulation process to reduce edge stress. In another example, a glass core 110 may be subject to edge stress and, as a result, damaged when TGVs are formed in it, e.g., when the TGVs 162 as shown in FIG. 2 are formed. FIG. 4 illustrates various surfaces 190 of a glass core 110 to which one or more techniques for edge stress reduction as described herein may be applied to reduce edge stress, according to some embodiments of the present disclosure. As shown in FIG. 4, a glass core 110 may include a first surface 190-1 and an opposing second surface 190-2, which may, e.g., be bottom and top surfaces when the glass core 110 is included in a microelectronic assembly 100. A surface 190-3 may refer to the edge/sidewall of the glass core 110, i.e., a surface that extends between the first surface 190-1 and the second surface 190-2. FIG. 4 further illustrates that if TGVs are to be formed in the glass core 110, then, first, openings 192 for future TGVs are formed, extending between the first surface 190-1 and the second surface 190-2. A surface 190-4 may then refer to sidewalls of the TGV openings 192. Any of the surfaces 190 as shown in FIG. 4 may be damaged and may need to be protected prior to including the glass core 110 in a microelectronic assembly 100, where the protection may include applying one or more techniques for edge stress reduction as described herein.

In general, surfaces (e.g., edges) of brittle materials such as glass can be subject to edge stress that may include mechanical stresses, thermal stresses, or a combination of both of these stresses, and the edge stress may lead to damage. Brittle materials like glass are characterized by their lack of ductility, meaning they do not deform plastically before fracturing. For example, when a cutting tool (e.g., the cutting tool 180) applies mechanical force to the surface of a glass core, it may initiate cracks or fractures at or near the cutting edge. The cutting tool may create a localized stress concentration (i.e., higher stress) at the edge where it contacts the glass core, which may lead to formation of cracks. Once cracks start to form, they may propagate through the glass. The stress concentration at the cutting edge encourages the cracks to extend further into the glass, and the inherent brittleness of glass makes it highly susceptible to crack propagation. Besides imposing mechanical stress onto glass, cutting can also generate thermal stress due to friction between the cutting tool and the glass, heating up the surface being cut. The heat can cause localized expansion and contraction of the glass, further promoting crack formation and propagation.

Cutting is not the only source of edge stress and damage that may affect glass cores. Even before cutting, glass may have tiny surface flaws or defects. These defects can act as initiation points for cracks, and additional mechanical or thermal stresses can exacerbate their growth, leading to edge damage. Furthermore, surfaces of a glass core may be subject to edge stress due to CTE mismatch between the glass core and materials deposited on the surfaces thereof. This may be the case when metals such as copper need to be placed on the surface of a glass core to serve as interconnects (e.g., various interconnects 108, described above) or conductive contacts (e.g., conductive contacts 126, 128, described above). Metals and materials that may be used for glass cores have significantly different CTEs. Metals have relatively high CTEs, meaning that they may expand and contract significantly with changes in temperature. Glass, on the other hand, has a much lower CTE and is less responsive to temperature changes. When a metal (e.g., various interconnects 108 or conductive contacts 126, 128, described above) is in close contact with glass, and the assembly is exposed to temperature variations such as heating or cooling, the metal will heat up or cool down much faster, and to a greater extent, than the glass. This leads to the generation of significant thermal stress at the interface between the two materials. The high thermal stress can exceed the strength of the glass, leading to the formation of cracks, which may then propagate and compromise the structural integrity of the glass. Even if cracks don't form immediately, the repeated thermal cycling can gradually weaken the glass surface, potentially leading to the development of surface flaws or micro-cracks. Prolonged exposure to CTE mismatch-induced stresses can cause gradual degradation of the glass, making it more prone to failure over time.

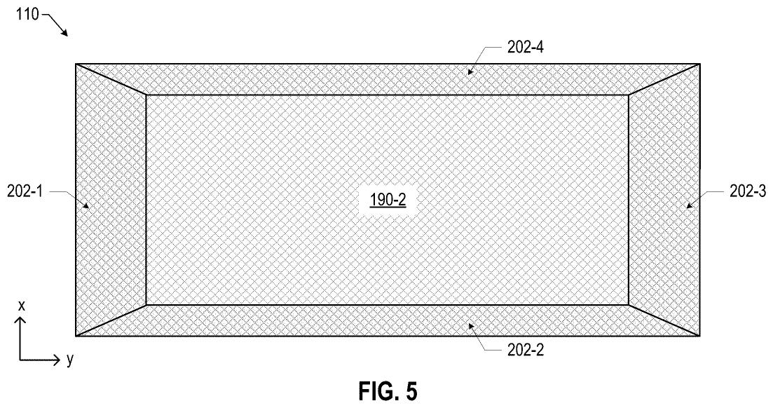

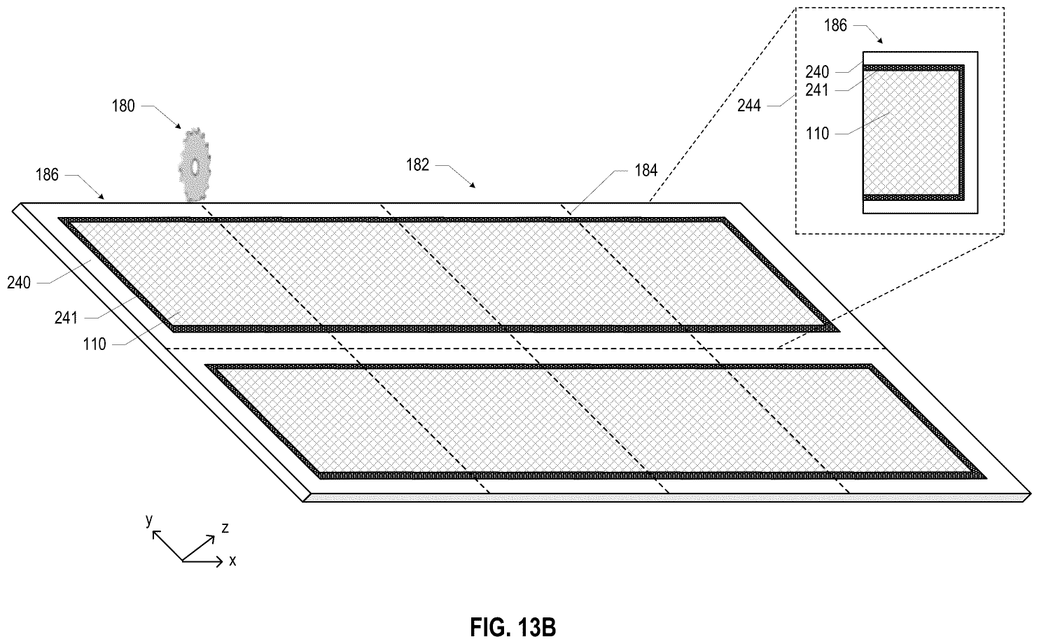

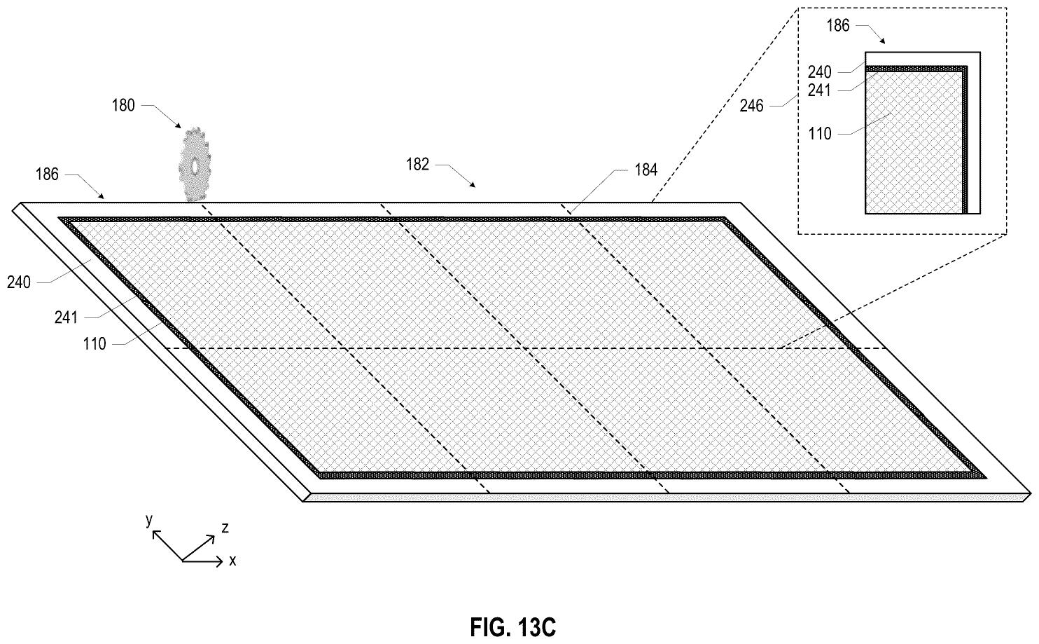

One or more techniques for edge stress reduction as described herein may be applied to a glass core 110 in order to reduce or eliminate damage at one or more surfaces of the glass core 110 before including the glass core 110 in a microelectronic assembly 100. Some of the techniques described herein may be applied to a glass core 110 during the singulation process, e.g., techniques described with reference to FIG. 5. Other techniques described herein may be applied to a glass core 110 after the singulation process has been carried out, e.g., techniques described with reference to FIGS. 6C-6D. Other techniques described herein may be applied to a glass core 110 prior to singulation, e.g., techniques described with reference to FIGS. 13A-13C.

One technique that may be used for edge stress reduction in glass cores is angling sidewalls of the glass cores relative to the bottom or top surfaces of the glass cores. This technique is illustrated with reference to FIG. 5 and FIGS. 6A-6E.

FIG. 5 illustrates a top-down perspective view of a glass core 110 with angled sidewalls, according to some embodiments of the present disclosure. In FIG. 5, individual sidewalls 202 are labeled as sidewalls 202-1, 202-2, 202-3, and 204-4, where sidewalls 202-1 and 202-3 are opposite one another, and sidewalls 202-2 and 202-4 are opposite one another. Either together or individually the sidewalls 202-1, 202-2, 202-3, and 204-4 are examples of the surface 190-3 of FIG. 4. Continuing with the notation used in FIG. 4, FIG. 5 further illustrates a surface 190-2. As used herein, a sidewall of a glass core may be described as being “angled” if an angle between the sidewall and the top or the bottom face (e.g., the top surface 190-2 or the bottom surface 190-1) of the glass core 110 is other than about 90 degrees. FIG. 5 illustrates that, in some embodiments, one or more of the sidewalls 202 may be angled by being at an angle other than 90 degrees to the surface 190-2. In such embodiments, a footprint of the glass core 110 may be larger than, and may encompass, a footprint of the bottom surface 190-1 or the top surface 190-2 of the glass core 110. As used herein, footprints are contours or projections in the x-y plane of the coordinate system 105 used in the present drawings. Although FIG. 5 illustrates all of the sidewalls 202 being angled sidewalls, in other embodiments, a glass core 110 may have only a subset of all sidewalls 202 being angled sidewalls (e.g., only one or two or three of the sidewalls 202).

Cross-sectional side views of glass cores 110 with angled sidewalls 202 according to some embodiments of the present disclosure are illustrated in FIGS. 6A-6E, showing different examples of the glass core 110 of FIG. 5. FIG. 6A illustrates a glass core 110 where a given sidewall 202 (e.g., a sidewall 202-3) may have a portion 204-1 slanted from the bottom surface 190-1 towards the middle of the glass core 110 and a portion 204-2 slanted from the top surface 190-2 towards the middle of the glass core 110, until the portions 204-1 and 204-2 meet each other, e.g., at about the middle of the glass core 110 (the middle being a portion of the glass core substantially between the surfaces 190-1 and 190-2). FIG. 6B illustrates a glass core 110 where a given sidewall 202 (e.g., a sidewall 202-3) has the portions 204-1 and 204-2 cut at an angle as in FIG. 6A, but the angling stops before reaching the middle of the glass core 110 and then the remainder of the singulation is performed at about a 90 degrees angle to form a portion 204-3 of the sidewall 202. FIG. 6C illustrates a glass core 110 where a given sidewall 202 (e.g., a sidewall 202-3) has the portions 204-1 and 204-2 cut at an angle as in FIG. 6A, and further has a portion 204-3 between the portions 204-1 and 204-2 as in FIG. 3, but the portion 204-3 is rounded. For either FIG. 6B or FIG. 6C, an angle between the portion 204-3 and either one of the surfaces 190-1 or 190-2 may be different from an angle between the portion 204-1 and the bottom surface 190-1 and/or different from an angle between the portion 204-2 and the top surface 190-2. FIG. 6D illustrates a glass core 110 where the entirety of a given sidewall 202 (e.g., a sidewall 202-3) is rounded. FIG. 6E illustrates that, in some embodiments, build-up layers 208 may be provided on the bottom surface 190-1 or the top surface 109-2 of the glass core 110, individually labeled as build-up layers 208-1 and 208-2, respectively.

In general, for various embodiments of angled sidewalls 202, an angle between a sidewall 202 and the surface 190-1 or 190-2 may be greater than 90 degrees. In various embodiments, an angle between a sidewall 202 and the surface 190-1 or 190-2 as measured away from the 90 degree angle may be between about 2 and 80 degrees, e.g., between about 5 and 60 degrees, or between about 5 and 30 degrees. Examples of this angle include an angle between a portion 204-1 and the dashed line 206 shown in FIG. 6A, or an angle between a portion 204-2 and the dashed line 206 shown in FIG. 6A; the same applies to FIGS. 6B-6E, where the line 206 is not shown in order to not clutter the drawings). Such angling may be achieved during singulation process by performing a singulation cut at an angle other than 90 degrees with respect to the surfaces 190-1 and/or 190-2. In some embodiments, a laser may be used to ablate material of the glass core 110 from the edges of unit boundaries (e.g., from the edges of the individual units 186 described above). In other embodiments, a cutting tool 180 (e.g., a singulation blade) may be lowered down to the larger block 182 of FIG. 3 at an angle other than 90 degrees. In some further embodiments, singulation using the cutting down 180 at an angle other than 90 degrees may be supplemented with the use of a laser to ablate material of the glass core 110 from the edges of unit boundaries, e.g., to create angled greater than about 25 degrees. Diffraction characteristics of the sidewalls 202 of a glass core 110 may reveal which processes were used to create angled sidewalls.

FIGS. 6A-6E illustrate that substantially the same angle is formed where the bottom surface 190-1 meets a portion of the sidewall 202 and where the top surface 190-2 meets a portion of the sidewall 202. However, in other embodiments, these angles may be different, e.g., if one angle is an angle as shown in FIG. 6A and another is an angle as shown in FIG. 6B.

In some embodiments, angled singulation may be applied to the larger block 182 as such (i.e., just to the glass core 110), e.g., to the glass core 110 implemented in a microelectronic assembly 100 shown in FIG. 2, or the glass core 110 implemented as the package interposer 1704 of the IC device assembly 1700. In other embodiments, angled singulation may be applied once one or more build-up layers are formed on the bottom or top surfaces of the glass core 110 (e.g., on the surfaces 190-1 or 190-2). FIG. 6E illustrates an embodiment with the build-up layers 208-1 and 208-2. In some embodiments, the build-up layers 208 may be layers of the substrate 107 above or below the glass core 110, as described with reference to FIG. 1. Thus, any of the build-up layers 208 may include a dielectric material 112 and a conductive material 108 arranged in the dielectric material 112 to provide conductive pathways through the build-up layer 208. For example, the conductive material may be a conductive trace 108A or a conductive via 108B. FIG. 6E further illustrates that, in some embodiments, in a cross-sectional side view in a plane substantially perpendicular to the plane of the glass core 110 (e.g., in a plane substantially perpendicular to the surfaces 190-1 or 190-2), sidewalls 202 of the glass core 110 may extend further out (e.g., along the y-axis of the example coordinate system 105 shown in the present drawings) than sidewalls of the build-up layers 208. In other words, a footprint of the glass core 110 may be larger than a footprint of a build-up layer 208. In some embodiments, a footprint of a build-up layer 208 may be enclosed within a footprint of the glass core 110. While FIG. 6E illustrates the glass core 110 having sidewalls 202 of a shape similar to that shown in FIG. 6A, in other embodiments, build-up layers 208 as shown in FIG. 6E may be provided for glass cores 110 having sidewalls 202 of any other shape described herein.

In some embodiments, angled singulation may be applied from only the top surface or only the bottom surface of the larger block 182. In other embodiments, angled singulation may be applied from both the top and the bottom surfaces by first performing angled cut from one side, then flipping the glass core over and performing the angled cut from the other side. Alternatively, angled singulation may be applied from both the top and the bottom surfaces substantially simultaneously. Either one of these approaches may be performed to fabricate glass cores as shown in FIGS. 6A and 6B. If further grinding is desired, then the profile of the sidewalls 202 may be modified using a polishing wheel or a cross belt to achieve the desired geometry, such as rounded edges as shown in FIG. 6C or FIG. 6D.

Having beveled edges at the sidewalls 202 between the bottom surface 190-1 and the top surface 190-2 according to any embodiments described with reference to FIG. 5 and FIGS. 6A-6E may advantageously lead to stronger edges of a glass core 110 and reduce edge stress compared to non-beveled edges. In addition, fabricating such beveled edges allows relatively simple post-processing to create rounded edges at the sidewalls 202 (e.g., as shown in FIG. 6C or FIG. 6D), which may further reduce overall edge stresses. Furthermore, by using angled singulation, the risk of damage from grinding the edges 190-3 during singulation may be reduced. Depending on the final choice of edge geometry, the grinding process conventionally applied to surfaces 190-3 (i.e., edges/sidewalls) of glass cores 110 may be entirely omitted or greatly reduced, reducing the risk of edge chips from the grinding.

While FIG. 5 and FIGS. 6A-6E illustrate how sidewalls of the glass cores may be angled (e.g., slanted, beveled, and/or at least partially rounded) to reduce edge stress, another technique that may be used for edge stress reduction in glass cores is rounding or flattening corners of the sidewalls. Examples of this are shown in FIGS. 7A-7B, illustrating top-down perspective views of glass cores with rounded or flattened corners, according to some embodiments of the present disclosure. FIG. 7A illustrates a glass core 110 with rounded corners where adjacent sidewalls 202 meet one another. As shown in FIG. 7A, in some embodiments, a corner where a sidewall 202-1 meets adjacent sidewall 202-2 may be rounded, a corner where a sidewall 202-2 meets adjacent sidewalls 202-3 may be rounded, a corner where a sidewall 202-3 meets adjacent sidewall 202-4 may be rounded, and a corner where a sidewall 202-4 meets adjacent sidewalls 202-1 may be rounded. In other embodiments, only a subset of these corners (e.g., one or two or three of these corners) may be rounded. FIG. 7B illustrates a glass core 110 with flattened corners where adjacent sidewalls 202 meet one another. As shown in FIG. 7B, in some embodiments, a corner where a sidewall 202-1 meets adjacent sidewall 202-2 may be flattened (thus forming a flattened corner sidewall 203-1 in between), a corner where a sidewall 202-2 meets adjacent sidewalls 202-3 may be flattened (thus forming a flattened corner sidewall 203-2 in between), a corner where a sidewall 202-3 meets adjacent sidewall 202-4 may be flattened (thus forming a flattened corner sidewall 203-3 in between), and a corner where a sidewall 202-4 meets adjacent sidewalls 202-1 may be flattened (thus forming a flattened corner sidewall 203-4 in between). In other embodiments, only a subset of these corners (e.g., one or two or three of these corners) may be flattened. Thus, FIGS. 7A-7B illustrate that, in some embodiments of the glass core 110, in a top-down plane view, at least one corner of the sidewall 190-3 of the glass core 110 may be rounded or flattened. Expressed differently, in the top-down plane view of a glass core 110, an angle between a first portion of the sidewall and a second portion of the sidewall, adjacent to the first portion of the sidewall (e.g., an angle between a sidewall 202-1 and a flattened corner sidewall 203-4, an angle between a sidewall 202-4 and a flattened corner sidewall 203-4, etc.), may be greater than 90 degrees but less than 180 degrees. In general, the corners of the sidewalls 202 of a glass core are not limited to the illustrations of FIGS. 7A-7B but may be of any rounded, chamfered, or another shape that is different from 90 degrees or sharp (i.e., less than 90 degrees) corners, which may reduce stress concentration zones and, thereby, reduce the susceptibility of the glass core 110 to crack formation and propagation. Varying the shapes of the corners of the sidewalls 202 from

FIGS. 7A-7B illustrate embodiments of the glass cores 110 where the sidewalls 202 are angled by being at an angle other than 90 degrees to the surface 190-2, similar to the illustration of FIG. 5. Such angling may be as described with any of FIGS. 6A-6E. Thus, FIGS. 7A-7B illustrate glass cores 110 that have, both, rounded or flattened corners and the sidewalls 202 that are angled. In this case, a footprint of the glass core 110 may be larger than, and may encompass, a footprint of the bottom surface 190-1 or the top surface 190-2 of the glass core 110, as illustrated in FIGS. 7A-7B. In other embodiments, a glass core 110 may have rounded or flattened corners as described herein, but where the sidewalls 202 are not angled. In such embodiments of a glass core 110 with rounded or flattened corners, a footprint of the glass core 110 may be substantially the same as, and may substantially overlap with, a footprint of the bottom surface 190-1 or the top surface 190-2 of the glass core 110 (not shown in the present drawings).

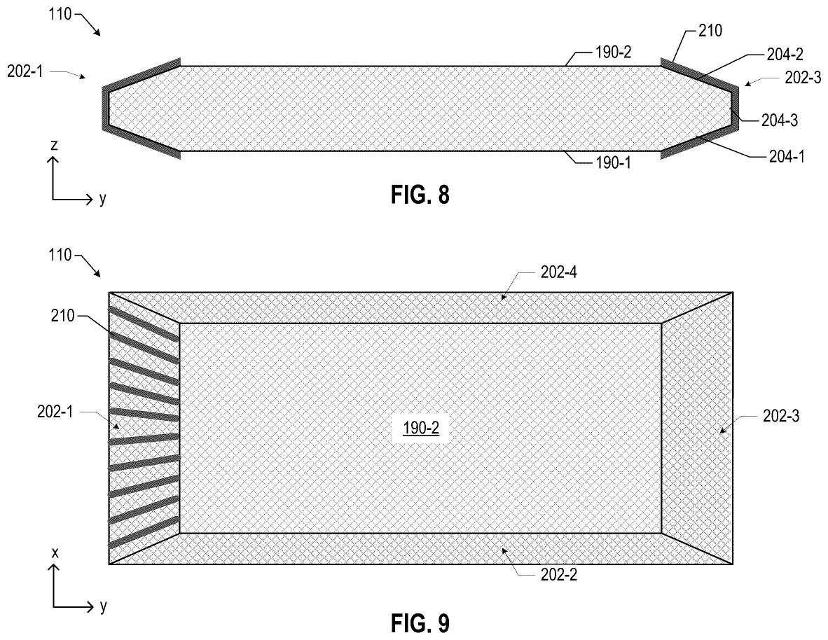

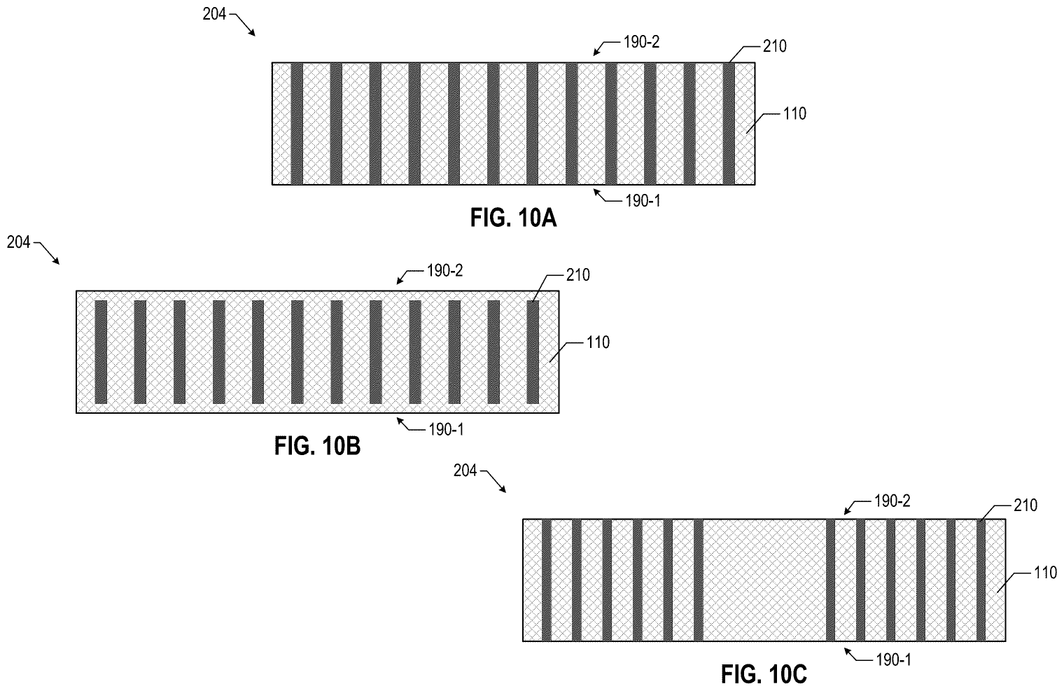

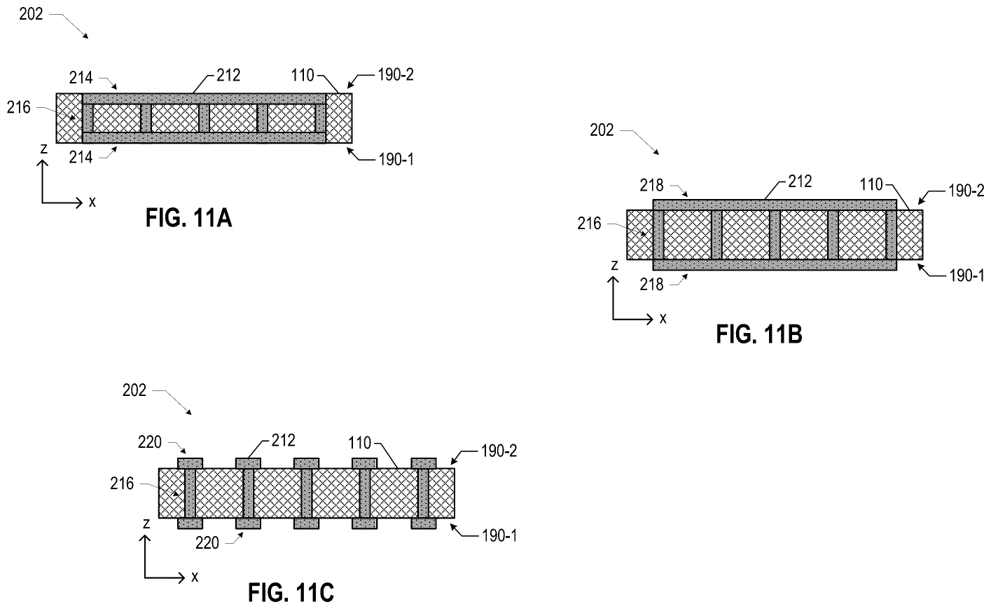

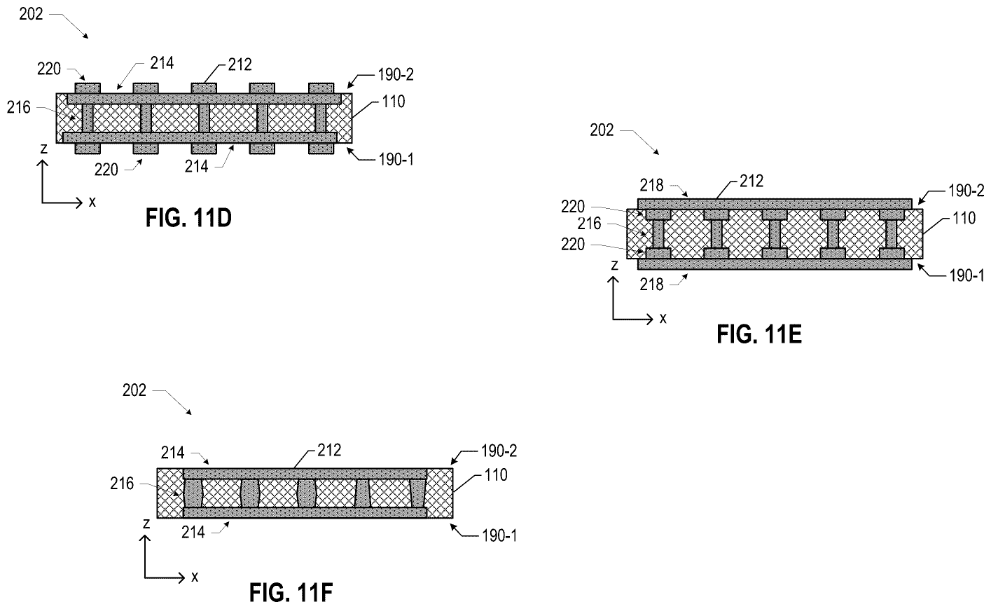

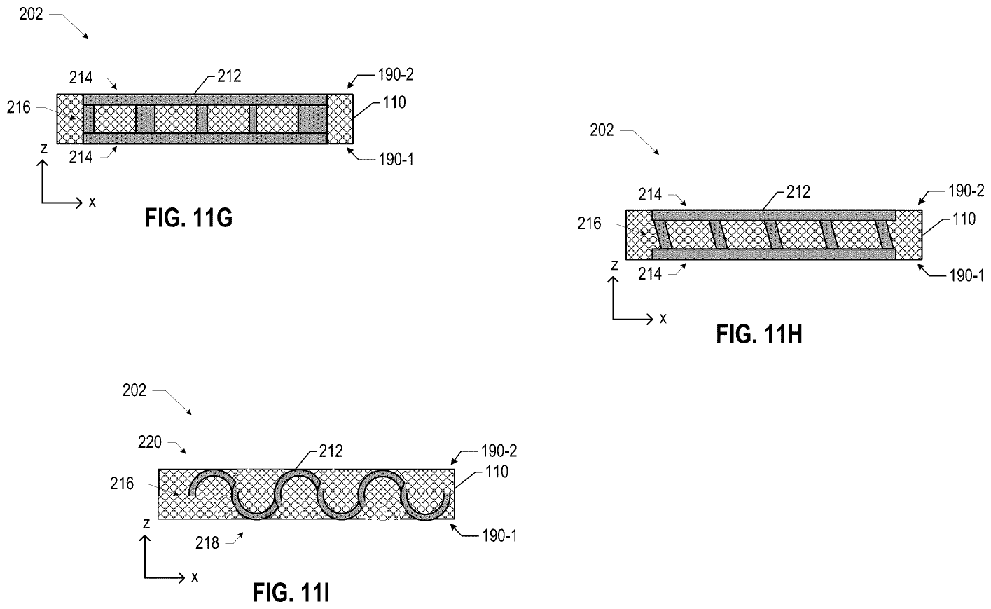

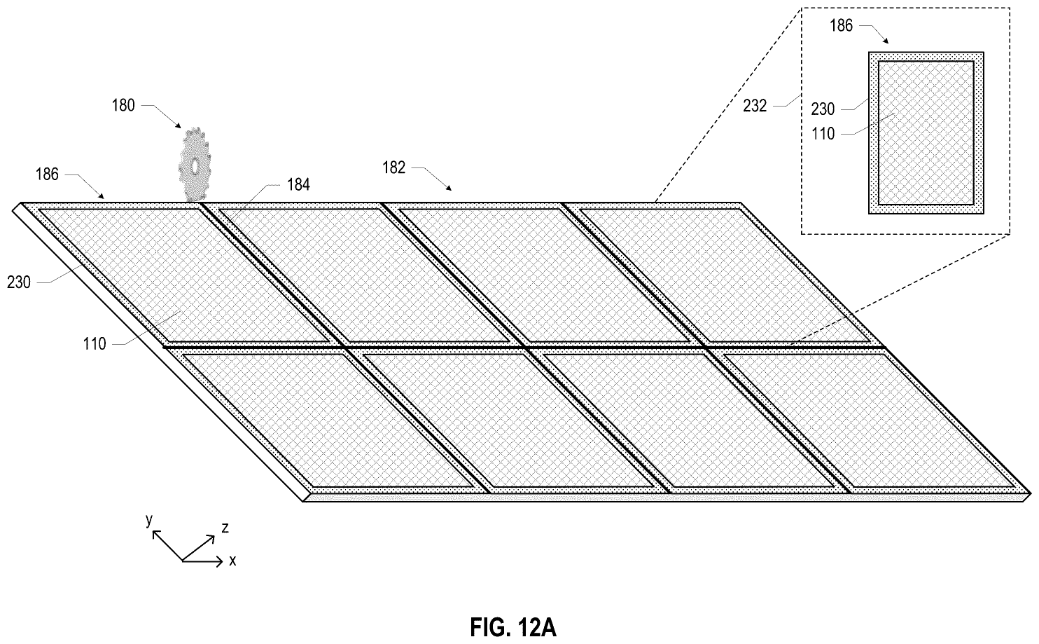

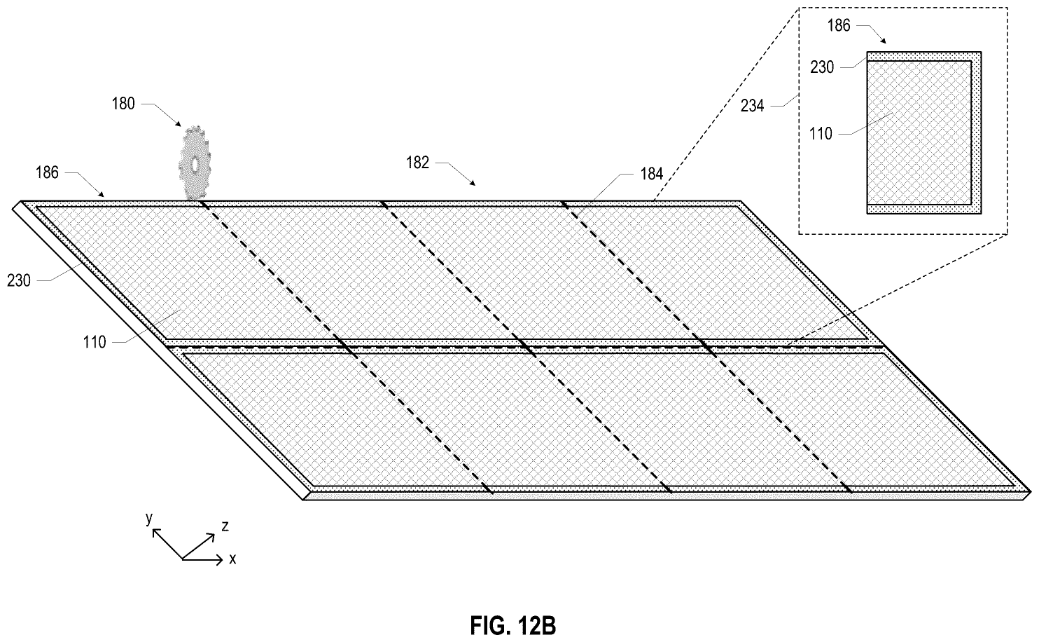

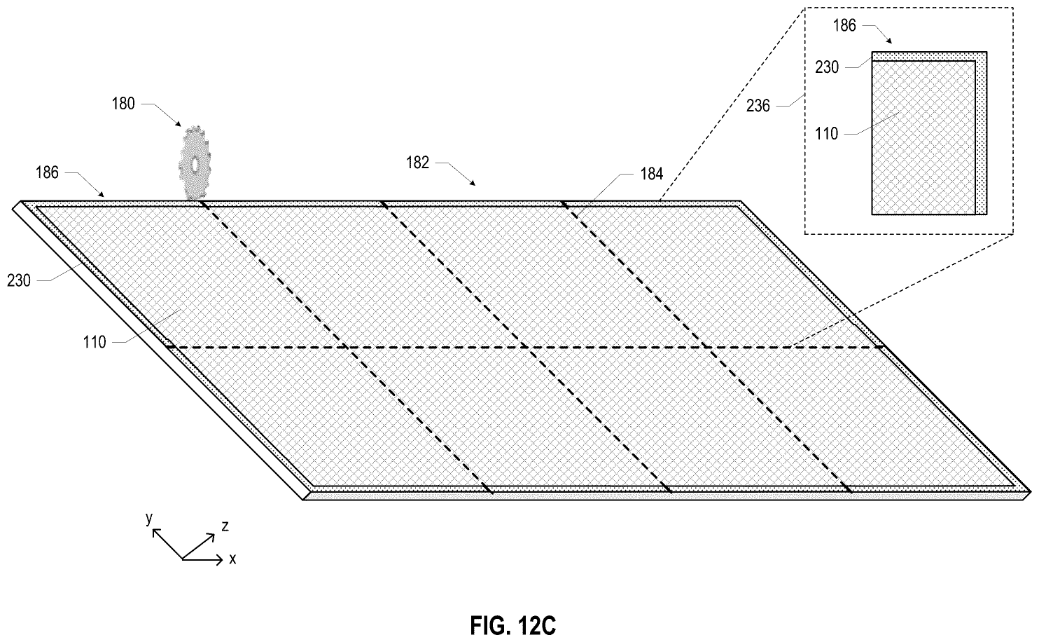

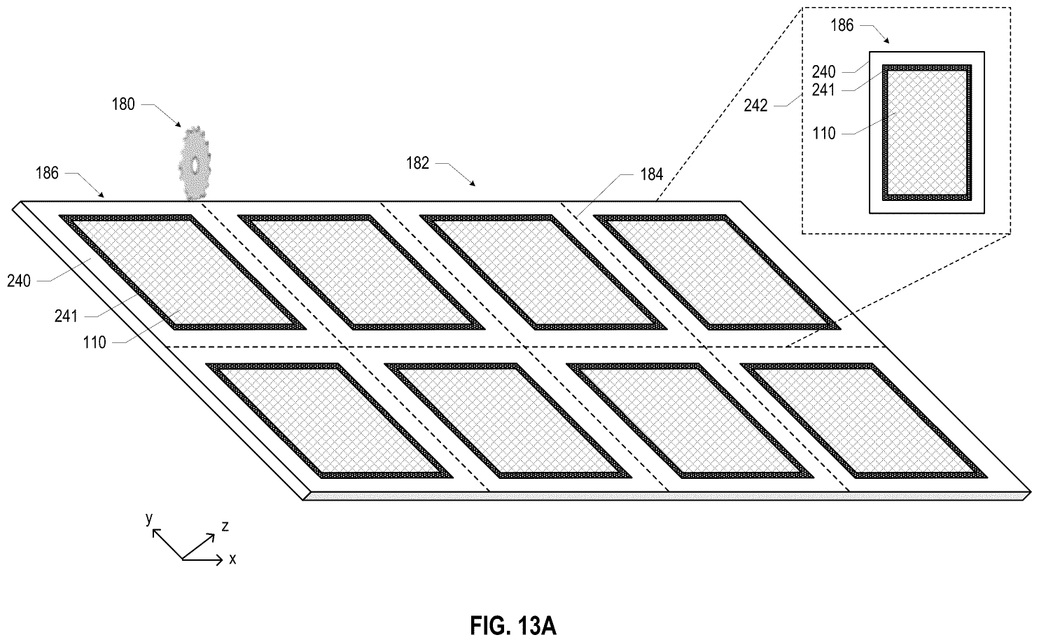

Yet another technique that may be used for edge stress reduction in glass cores is providing patterns of another material on at least portions of one or more sidewalls of a glass core. In some embodiments, the material of the patterns may be a metallic material such as copper, as illustrated with reference to FIG. 8. FIG. 9, and FIGS. 10A-10C. In other embodiments, the material of the patterns may be a polymer material such as resin or epoxy, as illustrated with reference to FIGS. 12A-12C and FIGS. 11A-11I. Embodiments of glass cores with patterns of a metallic material or a polymer material are based on recognition that such materials are elastic and, therefore, may be used to hold the glass core together.

FIG. 8 illustrates a cross-sectional side view of a glass core 110 with one or more patterns of a metallic material 210 on at least portions of sidewalls 202, according to some embodiments of the present disclosure. The metallic material 210 may include any suitable metal such as copper, tungsten, ruthenium, aluminum, titanium, or tantalum In some embodiments, the metallic material 210 may be a pure metal or a metal alloy, while in other embodiments the metallic material 210 may be a nitride or a carbide of one of the metals.

FIG. 8 illustrates a glass core 110 having sidewalls 202 of a shape similar to that shown in FIG. 6B, where a given sidewall 202 may include portions 204-1, 204-2, and 204-3. As shown in FIG. 8, in some embodiments, patterns of the metallic material 210 may be provided on all of the portions 204 of a sidewall 202 and the metallic material 210 may be materially continuous across the different portions 204 of a sidewall 202. However, in other embodiments, the metallic material 210 may be provided on only some, but not all, of the different portions 204 of a sidewall 202. Some examples include the metallic material 210 being provided on a portion 204-1, but not on portions 204-2 and 204-3; the metallic material 210 being provided on a portion 204-2, but not on portions 204-1 and 204-3; the metallic material 210 being provided on a portion 204-3, but not on portions 204-1 and 204-2; the metallic material 210 being provided on portions 204-1 and 204-3, but not on a portion 204-2; the metallic material 210 being provided on portions 204-2 and 204-3, but not on a portion 204-1; or the metallic material 210 being provided on portions 204-1 and 204-2, but not on a portion 204-3. In various embodiments, if the metallic material 210 is provided on two or more adjacent portions 204, it may be either material continuous or materially discontinuous (e.g., spaced apart) between the different portions 204.

While FIG. 8 illustrates the glass core 110 having sidewalls 202 of a shape similar to that shown in FIG. 6B, in other embodiments, patterns of the metallic material 210 as shown in FIG. 8 may be provided for glass cores 110 having sidewalls 202 of any other shape described herein.

FIG. 9 illustrates a top-down perspective view of a glass core 110 with one or more patterns of a metallic material on at least portions of sidewalls, according to some embodiments of the present disclosure. FIG. 9 illustrates a pattern of the metallic material 210, provided as substantially straight lines, only on the sidewall 202-1. In other embodiments, similar patterns of the metallic material 210 may be provided on other sidewalls 202 of the glass core 110 of FIG. 9. Furthermore, in other embodiments, patterns of the metallic material 210 may include shapes other than substantially straight lines, such as one or more curves or closed contours of the metallic material 210.

FIG. 9 illustrates an embodiment of the glass core 110 where the sidewalls 202 are angled by being at an angle other than 90 degrees to the surface 190-2, similar to the illustration of FIG. 5. Such angling may be as described with any of FIGS. 6A-6E. Thus, FIG. 9 illustrates a glass core 110 that have, both, one or more patterns of the metallic material 210 on the sidewalls 202 and the sidewalls 202 that are angled. In this case, a footprint of the glass core 110 with one or more patterns of the metallic material 210 on the sidewalls 202 may be larger than, and may encompass, a footprint of the bottom surface 190-1 or the top surface 190-2 of the glass core 110, as illustrated in FIG. 9. In other embodiments, a glass core 110 may have one or more patterns of the metallic material 210 on the sidewalls 202 as described herein, but where the sidewalls 202 are not angled. In such embodiments of a glass core 110 with one or more patterns of the metallic material 210 on the sidewalls 202, a footprint of the glass core 110 may be substantially the same as, and may substantially overlap with, a footprint of the bottom surface 190-1 or the top surface 190-2 of the glass core 110 (not shown in the present drawings).

FIGS. 10A-10C illustrate top-down views of example portions 204 of a glass core sidewall with one or more patterns of a metallic material, according to some embodiments of the present disclosure. The portions 204 shown in FIGS. 10A-10C may be examples of how the metallic material 210 may be arranged on any of the portions 204 of FIG. 8 or FIG. 9 but flattened out to be shown in a single plane. FIG. 10A illustrates an embodiment where the metallic material 210 may be provided in a pattern that extends between, and is in contact with, the bottom surface 190-1 and the top surface 190-2 of a glass core 110. FIG. 10B illustrates an embodiment where the metallic material 210 may be provided in a pattern that extends between, but is spaced apart from, the bottom surface 190-1 and/or the top surface 190-2 of a glass core 110. FIG. 10A and FIG. 10B illustrate embodiments where the lines of the metallic material 210 are uniformly distributed. FIG. 10C illustrates an embodiment where the metallic material 210 is not uniformly distributed in a pattern, e.g., there is less of the metallic material 210 in the center of the portion 204 than there are near the edges of the portion 204. In some embodiments, a width of a line of the metallic material 210, e.g., a dimension measured along the horizontal axes shown in FIGS. 10A-10C, may be between about 50 nanometers and 200 micron, e.g., between about 100 nanometers and 100 micron.

In further embodiments, the metallic material 210 may be provided in other patterns than what is shown in FIG. 8, FIG. 9, and FIGS. 10A-10C. Any amount of the metallic material 210 on any portion of the sidewalls 202 of a glass core 110 may help reduce edge stress in the glass core 110. Even though the metallic material 210 may be provided in the form of lines on the sidewalls 202 in some embodiments, such metallic material 210 would be different from conventional conductive traces that may be provided on the glass core 110 in that the metallic material 210 would not be electrically connected to any power, signal, or ground sources. In other words, the metallic material 210 may be electrically floating and electrically insulated from all electrically conductive structures in or adjacent to the glass core 110 that may, in operation, be electrically connected to any power, signal, or ground sources.

While descriptions of FIG. 8, FIG. 9, and FIGS. 10A-10C refer to the metallic material 210 in various patterns, these patterns may be substantially as described above if instead of the metallic material 210 a polymer material such as resin or epoxy was used. Thus, descriptions of FIG. 8, FIG. 9, and FIGS. 10A-10C also cover embodiments where the reference numeral “210” refers to a polymer material. In some embodiments, the metallic material 210 may include metallic particles distributed in a matrix or a surrounding medium of a polymer material. In some such embodiments, the matrix or the surrounding medium of the polymer material may be electrically non-conductive. In some embodiments, the metallic material 210 may not include any polymer materials. In some embodiments, the metallic material 210 may be an electrically conductive material.

FIGS. 11A-11I and FIGS. 12A-12C provide additional embodiments where patterns of a polymer material 212 may be provided on sidewalls 202 of a glass core 110 in order to reduce edge stress in the glass core 110. As used herein, a polymer material provided on the sidewalls 202, e.g., the polymer material 212, refers to a material that includes large molecules composed of repeating subunits known as monomers. In some embodiments, the polymer material 212 may include one or more resins. Resins are a broad category of synthetic or natural compounds that have a viscous or liquid consistency. They can be derived from various sources and can be thermosetting (harden permanently when cured) or thermoplastic (soften when heated and harden when cooled). In some embodiments, the polymer material 212 may include one or more epoxies. Epoxies are a specific type of resin known for their excellent adhesive and structural properties. They may be created through a chemical reaction between two components: epoxy resin and a hardener (or curing agent). When these two components are mixed together, they undergo a curing process that results in a rigid and durable material. In some embodiments, the polymer material 212 may include polyurethane dimethacrylate (PUDMA). In some embodiments, the polymer material 212 may include a polymer material that has relatively high toughness to absorb the shocks, high cohesion or self-adhesion to not break under stress, be compatible with thermal and chemical processes that are to be applied to the glass core 110 later, be able to fill TGVs fully, and be able to shrink during curing and/or cooling to further increase the compressive stress on the unit.

FIGS. 11A-11| illustrate cross-sectional side views of glass cores with one or more patterns of a polymer material on at least portions of sidewalls 202, according to some embodiments of the present disclosure. While FIGS. 11A-11| illustrate sidewalls 202, descriptions provided for these drawings are equally applicable if the sidewalls 202 were portions 204 of the sidewalls 202. In some embodiments, the sidewalls 202 with one or more patterns of a polymer material 212 may be angled sidewalls as described above. In other embodiments, the sidewalls 202 with one or more patterns of a polymer material 212 may be not angled.

FIG. 11A illustrates an embodiment where a pattern of the polymer material 212 includes the polymer material 212 embedded in a trench 214 connecting a row of pillars 216. In some embodiments, one trench 214 may be provided at the bottom surface 190-1 of the sidewall 202 and another trench 214 may be provided at the top surface 190-2 of the sidewall 202, as shown in FIG. 11A. The trench 214 may be etched or lasered from the glass core 110 or from the lower build-up layer provided over the glass core 110, e.g., from the lower one of the build-up layers 208 as described above. In some embodiments, a depth of the trench 214, a dimension measured along the z-axis shown in FIG. 11A, may be between 250 nanometers and 500 microns, e.g., between 500 nanometers and 100 microns. In some embodiments, a width of the trench 214, a dimension measured along the y-axis shown in FIG. 11A, may be between about 250 nanometers and 750 microns, e.g., between about 500 nanometers and 500 microns. In some embodiments, a width of the pillar 216, a dimension measured along the x-axis shown in FIG. 11A, may be between about 500 nanometers and 750 microns, e.g., between about 1 micron and 500 microns.

FIG. 11B illustrates an embodiment where the trenches 214 of FIG. 11A are replaced with lines 218 of the polymer material 212. In some embodiments, one line 218 may be provided over the bottom surface 190-1 of the sidewall 202 and another line 218 may be provided over the top surface 190-2 of the sidewall 202, as shown in FIG. 11B. The one or more lines 218 may connect a row of pillars 216. The pillars 216 may be substantially the same as those of FIG. 11A, but now extending from the bottom surface 190-1 to the top surface 190-2. In some embodiments, the depth and/or the width of a line 218 may be substantially the same as those provided for the trench 214. Using the lines 218 may help improve uniformity of the build-up layers that may be provided over the bottom surface 190-1 and/or over the top surface 190-2 of the sidewall 202.

FIG. 11C illustrates an embodiment where the lines 218 of FIG. 11B are replaced with pads 220 of the polymer material 212. In some embodiments, the depth and/or the width of a pad 220 may be substantially the same as those provided for the line 218, but individual pads 220 may be materially discontinuous from one another and, thus, may have shorter lengths, a dimension measured along the x-axis shown in FIG. 11C, than a length of the line 218 or the trench 214. In some embodiments, a length of a pad 220 may be between about 500 nanometers and 750 microns, e.g., between about 1 micron and 500 microns. The pads 220 may be advantageous in that they take up less space which increases design flexibility and may decrease the risk of failure of the pillars 216 to separate from the surface.

FIG. 11D illustrates an embodiment combing the pads 220 as shown in FIG. 11C with the trenches 214 and the pillars 216 as shown in FIG. 11A. Such an embodiment may be advantageous in its ability to further reduce edge stress in the glass core 110 because more of the polymer material 212 is applied at the surface 202.

FIG. 11E illustrates an embodiment combing the pads 220 as shown in FIG. 11C but now recessed to be below the surfaces 190-1 and 190-2 with the lines 218 and the pillars 216 as shown in FIG. 11B. Similar to FIG. 11D, such an embodiment may be advantageous in its ability to further reduce edge stress in the glass core 110 because more of the polymer material 212 is applied at the surface 202.

FIG. 11F illustrates that, in some embodiments, different ones of the pillars 216 may have different shapes, which may either be deliberate or inevitable as a result of fabrication variations. FIG. 11G illustrates that, in some embodiments, different ones of the pillars 216 may have different diameters, which may improve adhesion. FIG. 11H illustrates that, in some embodiments, some or all of the pillars 216 may be slanted/angled, which may increase strength by distributing any shock among a longer length (since the shock and the polymer material 212 are at different angles). FIG. 11I illustrates that, in some embodiments, the polymer material 212 may be provided in shapes that include curved or rounded portions, which may further increase strength. While FIGS. 11F-11H illustrate the pillars 216 in combination with the trenches 214, descriptions of these drawings are equally applicable to patterns of the polymer material 212 that include features other than, or in addition to, the trenches 214, e.g., to patterns of the polymer material 212 that include lines 218, pads, 220, or shapes with curved or rounded portions as shown in FIG. 111.

The patterns of the polymer material 212 as described with reference to FIGS. 11A-11I may be referred to as “stitches” of the polymer material 212 because they include portions near or at the surfaces 190-1 and 190-2 (e.g., trenches 214, lines 218, or pads 220), as well as portions that extend and connect the portions near or at the surfaces 190-1 and 190-2 (e.g., pillars 216). Such stitches may efficiently counteract tensile forces pulling the glass core 110 apart, since such a movement would pull the stitch apart first, thus reducing the possibility of the glass core 110 splitting along a plane substantially parallel to and being between the surfaces 190-1 and 190-2 (e.g., a plane around the centerline of the glass core in the z-axis direction). The patterns of the polymer material 212 as shown in FIGS. 11A-11I are not exhaustive and other patterns along the lines of the considerations provided herein are possible and are within the scope of the present disclosure.

FIGS. 11A-11I describe the patterns of the polymer material 212 being on sidewalls 202 of glass cores 110, indicating that, in some embodiments, such patterns may be provided after singulation. In other embodiments, patterns as described with reference to FIGS. 11A-11I may be provided within/on a larger block of a glass core before it is cut into individual units. Examples of such embodiments are shown in FIGS. 12A-12C, illustrating perspective views of glass cores 110 with one or more patterns of a polymer material on at least portions of sidewalls, according to some embodiments of the present disclosure. FIGS. 12A-12C illustrate singulation where a cutting tool 180 is used to cut a larger block 182 of glass core along lines 184, to separate the larger block 182 into individual units 186 which may then serve as glass cores 110 described herein. Singulation lines 184 are shown as thick solid lines in FIG. 12A and as dashed lines in FIGS. 12B-12C, where three such lines are shown to be parallel to the y-axis and one such line is shown to be parallel to the x-axis.

FIG. 12A provides an illustration similar to the illustration of FIG. 3A, except that, in FIG. 12A, prior to cutting, the larger block 182 is provided with polymer stitch regions 230 that may include patterns of polymers extending between the bottom surface 190-1 and the top surface 190-2 of the larger block 182 (i.e., extending in planes substantially perpendicular to the bottom surface 190-1 and the top surface 190-2 of the larger block 182). The patterns within the polymer stitch regions 230 may be any of the patterns described with reference to FIGS. 11A-11I. In the polymer stitch regions 230, the trenches 214 described with reference to FIGS. 11A-11I may be provided by etching out portions of the larger block 182 of the glass core, and the pillar portions 216 may be TGVs extending through the larger block 182. As shown in FIG. 12A, in some embodiments, the polymer stitch regions 230 may have portions that enclose the larger block 182 along its perimeter, as well as portions provided along the lines 184 where the cutting will take place during singulation (the lines 184 shown as thick solid lines in FIG. 12A, where three such lines are shown to be parallel to the y-axis and one such line is shown to be parallel to the x-axis). Providing patterns of the polymer material 212 in the polymer stitch regions 230 aligned with the singulation lines 184 and/or provided along the perimeter of the larger block 182 may help reduce or eliminate edge stress imposed on the individual units 186 of glass cores 110 caused by the singulation process. After the singulation process has taken place, individual units 186 may be as shown within an inset 232 in FIG. 12A, illustrating that portions of the polymer stitch regions 230 may remain around the perimeter of each individual glass core 110, enclosing the glass core 110.

FIG. 12B illustrates singulation process similar to that shown in FIG. 12A, except where the polymer stitch regions 230 are not provided along some of the singulation lines 184. In particular, FIG. 12B illustrates an embodiment where the polymer stitch regions 230 are provided around the perimeter of the larger block 182 and along the singulation line 184 that is parallel to the x-axis, but other the polymer stitch regions 230 are absent along the remainder of the singulation lines 184 that are parallel to the y-axis. After the singulation process has taken place, individual units 186 may be as shown within an inset 234 in FIG. 12B, illustrating that an individual glass core 110 may have portions of the polymer stitch regions 230 only around a portion, but not all, of the perimeter of the glass core 110, thus only partially enclosing the glass core 110. The inset 234 of FIG. 12B illustrates an individual unit 186 from the corner of the larger block 182, in which case the polymer stitch regions 230 may be on three sides of the glass core 110 and be absent on one side. However, if an individual unit 186 would be taken from a portion of the larger block 182 that is not at the corner, then the polymer stitch regions 230 would be on two opposite sides of the glass core 110 and be absent on the other two opposite sides (not shown).

FIG. 12C illustrates singulation process similar to that shown in FIG. 12A, except where the polymer stitch regions 230 are provided around the perimeter of the larger block 182 but otherwise not provided along the remainder of any of the singulation lines 184. After the singulation process has taken place, individual units 186 may be as shown within an inset 236 in FIG. 12C, illustrating that an individual glass core 110 may have portions of the polymer stitch regions 230 on, at most, two sides of the perimeter of the glass core 110, thus only partially enclosing the glass core 110. The inset 236 of FIG. 12C illustrates an individual unit 186 from the corner of the larger block 182, in which case the polymer stitch region 230 may be on two adjacent sides of the glass core 110 and be absent on two other adjacent sides. However, if an individual unit 186 was taken from a portion of the larger block 182 that is not at the corner, then the polymer stitch region 230 would be only on one side of the glass core 110 and be absent on the other three sides (not shown).

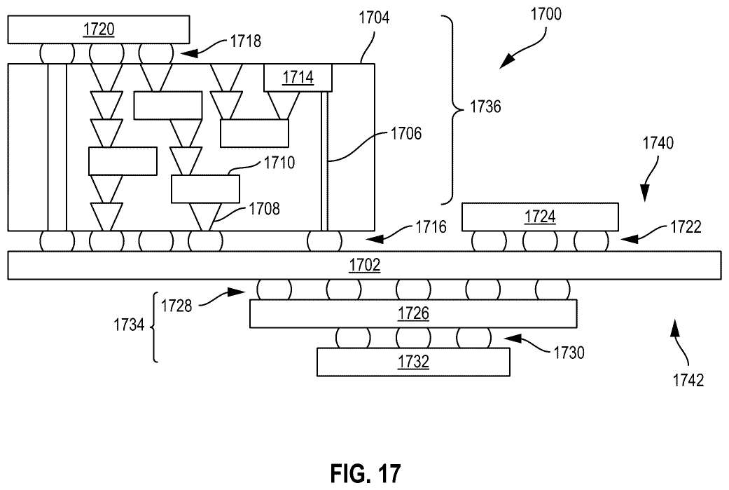

In some embodiments, the polymer stitch regions 230 remaining after singulation of any of FIGS. 12A-12C may be removed from the sidewalls 202 of the glass cores 110 of the individual units 186. In other embodiments, the polymer stitch regions 230 may be left on the individual units 186 after singulation to provide further edge stress reduction to the glass cores 110 at least partially enclosed within the polymer stitch regions 230. In some embodiments, the polymer stitch regions 230 may be left on the individual units 186 after singulation only for the duration of transportation and handling of the glass cores 110 and be removed prior to inclusion of the glass core 110 in a larger device. In other embodiments, at least portions of the polymer stitch regions 230 may be present around at least some of the sidewalls of a glass core 110 when a glass core 110 is included in a microelectronic assembly such as a microelectronic assembly 100 of FIG. 1 or 2, or when the glass core 110 is used as a package interposer 1704 of the IC device assembly 1700 of FIG. 17.

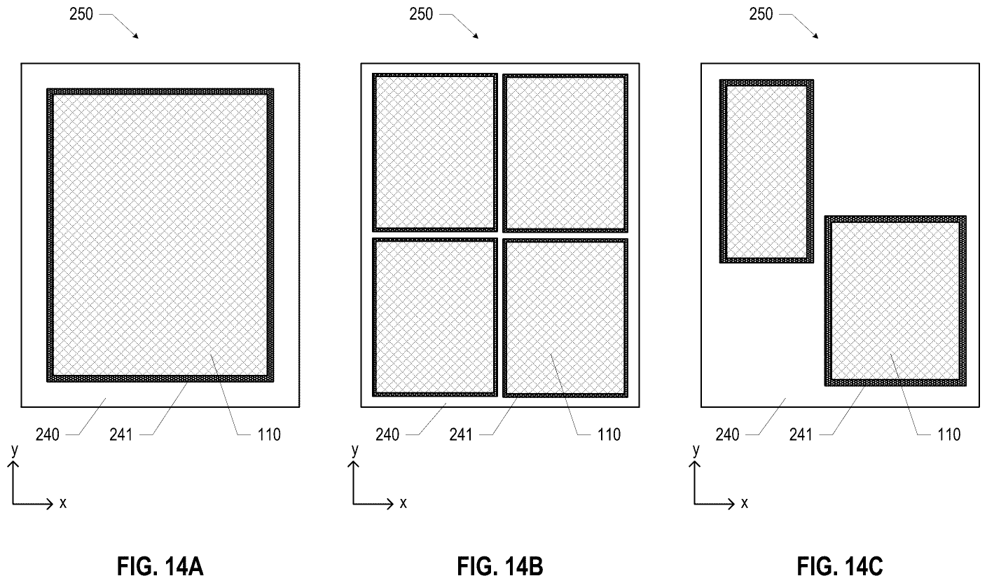

One more technique that may be used for edge stress reduction in glass cores is embedding glass cores in panels of organic materials, e.g., in organic bezels. This technique is illustrated with reference to FIGS. 13A-13C and FIGS. 14A-14C.

FIGS. 13A-13C illustrate perspective views of glass cores 110 embedded in panels of organic materials, according to some embodiments of the present disclosure. FIGS. 13A-13C illustrate singulation where a cutting tool 180 is used to cut a larger block 182 of glass core along lines 184, to separate the larger block 182 into individual units 186 which may then serve as glass cores 110 described herein. Singulation lines 184 are shown as dashed lines in FIGS. 13A-13C, where three such lines are shown to be parallel to the y-axis and one such line is shown to be parallel to the x-axis.

FIG. 13A provides an illustration similar to the illustration of FIG. 12A, except that, in FIG. 13A, prior to cutting, the glass cores 110 of future individual units 186 are embedded within panels of an organic material 240. In some embodiments, the organic material 240 may include any of the organic materials used in standard organic package manufacturing processes. In some embodiments, the organic material 240 may include materials such as organic build-up films, resins, epoxies, polyimides, polyester resins, phenolic resins, liquid crystal polymers, polycarbonates, polyethylenes, polypropylenes, or fluoropolymers. An adhesive material 241 may be used between a glass core 110 and an adjacent portion of the organic material 240 to promote mechanical attachment of the glass cores 110 within the panels of the organic material 240. In some embodiments, the adhesive material 241 may be a mold material, such as an organic polymer with inorganic silica particles. In some embodiments, the adhesive material 241 may be an insulator material such as an appropriate epoxy material. In some embodiments, the adhesive material 241 may include any molds or mold-like materials used in packaging applications, including for example, materials used in organic interposers, package supports and other such components. In some embodiments, the organic material 240 may extend substantially uniformly between the bottom surface 190-1 and the top surface 190-2 of the glass cores 110, enclosing or embedding sidewalls 202 of the glass cores 110. In some embodiments, the organic material 240 may be in a form of a bezel in that it may be raised or projected with respect to the glass core 110 and/or may border the glass core 110. After the singulation process has taken place, individual units 186 may be as shown within an inset 242 in FIG. 13A, illustrating that portions of the organic material 240, and the associated adhesive material 241, may remain around the perimeter of each individual glass core 110, enclosing the glass core 110. This illustrates that providing the organic material 240 as shown in FIG. 13A allows avoiding applying the cutting tool 180 directly to the glass cores 110 and cutting through the organic material 240 instead. Avoiding mechanical cutting through the glass cores 110 may significantly reduce the edge stress in the glass cores 110 and, consequently, reduce the risks of formation and propagation of defects in the glass cores 110. Furthermore, a panel of the organic material 240 that encloses sidewalls of a glass core 110 may serve as a protective feature during subsequent transportation and handling.

FIG. 13B illustrates singulation process similar to that shown in FIG. 13A, except where the organic material 240 encloses multiple individual units 186 by not being provided along portions of some of the singulation lines 184. In particular, FIG. 13B illustrates an embodiment where the organic material 240 is provided around the perimeter of the larger block 182 and along the singulation line 184 that is parallel to the x-axis, but otherwise the organic material 240 is absent along the remainder of the singulation lines 184 that are parallel to the y-axis. After the singulation process has taken place, individual units 186 may be as shown within an inset 244 in FIG. 13B, illustrating that an individual glass core 110 may have portions of the organic material 240 only around a portion, but not all, of the perimeter of the glass core 110, thus only partially enclosing the glass core 110. The inset 244 of FIG. 13B illustrates an individual unit 186 from the corner of the larger block 182, in which case the organic material 240 may be on three sides of the glass core 110 and be absent on one side. However, if an individual unit 186 would be taken from a portion of the larger block 182 that is not at the corner, then the organic material 240 would be on two opposite sides of the glass core 110 and be absent on the other two opposite sides (not shown).

FIG. 13C illustrates singulation process similar to that shown in FIG. 13A, except where the organic material 240 is provided around the perimeter of the larger block 182 but otherwise not provided along the remainder of any of the singulation lines 184. After the singulation process has taken place, individual units 186 may be as shown within an inset 246 in FIG. 13C, illustrating that an individual glass core 110 may have portions of the organic material 240 on, at most, two sides of the perimeter of the glass core 110, thus only partially enclosing the glass core 110. The inset 246 of FIG. 13C illustrates an individual unit 186 from the corner of the larger block 182, in which case the organic material 240 may be on two adjacent sides of the glass core 110 and be absent on two other adjacent sides. However, if an individual unit 186 was taken from a portion of the larger block 182 that is not at the corner, then the organic material 240 would be only on one side of the glass core 110 and be absent on the other three sides (not shown).

In some embodiments, the organic material 240 remaining after singulation of any of FIGS. 13A-13C may be removed from the sidewalls 202 of the glass cores 110 of the individual units 186. In other embodiments, the organic material 240 may be left on the individual units 186 after singulation to provide further edge stress reduction to the glass cores 110 at least partially enclosed within the polymer stitch regions 230. In some embodiments, the organic material 240 may be left on the individual units 186 after singulation only for the duration of transportation and handling of the glass cores 110 and be removed prior to inclusion of the glass core 110 in a larger device. In other embodiments, at least portions of the organic material 240 (and the associated adhesive material 241) may be present around at least some of the sidewalls of a glass core 110 when a glass core 110 is included in a microelectronic assembly such as a microelectronic assembly 100 of FIG. 1 or 2, or when the glass core 110 is used as a package interposer 1704 of the IC device assembly 1700 of FIG. 17.

There are several ways how glass cores 110 may be embedded within panels of organic materials 240. Some examples are shown in FIGS. 14A-14C, illustrating top-down views of example glass core units 250 with one or more glass cores embedded in organic panels, according to some embodiments of the present disclosure.

FIG. 14A illustrates an embodiment of a glass core unit 250 where a single glass core 110 is embedded within a materially continuous panel of the organic material 240, where an adhesive material 241 may be provided between the glass core 110 and the organic material 240. The glass core unit 250 is similar to the individual units 186 of FIG. 13A. In some embodiments, a width of the organic material 240 (a dimension measured in a direction perpendicular from the adjacent sidewall of the glass core 110) may be between about 5 microns and 50 millimeters, e.g., between about 10 microns and 25 millimeters, depending on the panel utilization. In some embodiments, a distance between the organic material 240 and the nearest portion of the glass core 110 (a dimension that is substantially the width of the adhesive material 241) may be between about 50 nanometers and 10 millimeters, e.g., between about 100 nanometers and 3 millimeters.

FIG. 14B illustrates an embodiment of a glass core unit 250 where multiple glass cores 110 are embedded within a materially continuous panel of the organic material 240, where an adhesive material 241 may be provided between the glass cores 110 and the organic material 240. The glass core unit 250 of FIG. 14B may be referred to as “quarter panel embedding” because there are four glass cores 110 are of substantially the same dimensions and are arranged substantially symmetrically within the organic material 240. In other embodiments, any other number of two or more glass cores 110 may be embedded within a single panel of the organic material 240.

FIG. 14C illustrates an embodiment of a glass core unit 250 where multiple glass cores 110 of different dimensions/shapes are embedded within a materially continuous panel of the organic material 240, where an adhesive material 241 may be provided between the glass cores 110 and the organic material 240. The glass core unit 250 of FIG. 14C may be referred to as “patch embedding” because some of the glass cores 110 have different dimensions and/or different shapes/geometry, and the individual glass cores 110 may be considered to be patches. In other embodiments, any other number of two or more glass cores 110, of any dimensions/shapes may be embedded within a single panel of the organic material 240.

Various arrangements of the microelectronic assemblies 100 and glass cores 110 as shown in FIGS. 1-14 do not represent an exhaustive set of microelectronic assemblies and glass cores in which various techniques for edge stress reduction as described herein may be used, but merely provide some illustrative examples. In particular, the number and positions of various elements shown in FIGS. 1-14 is purely illustrative and, in various other embodiments, other numbers of these elements, provided in other locations relative to one another may be used in accordance with the general architecture considerations described herein. For example, although not specifically shown in the present drawings, in some embodiments, a microelectronic assembly 100 may include a redistribution layer (RDL) between any pair of layers shown in FIG. 1 and FIG. 2, the RDL including a plurality of interconnect structures (e.g., conductive lines and conductive vias) to assist routing of signals and/or power between components. In another example, although also not specifically shown in the present drawings, in some embodiments, a package substrate 102 of a microelectronic assembly 100 may include one or more recesses. In such embodiments, a bottom surface of a recess in the package substrate 102 may be provided by solid material of the package substrate 102. A recess may be formed in a package substrate 102 in any suitable manner (e.g., via three-dimensional printing, laser cutting or drilling the recess into an existing package substrate, etc.). At least a portion of the substrate 107 or the glass core 110 may be positioned over or at least partially in such a recess. In yet another example, features of any one of FIGS. 1-14 may be combined with features of any other one of FIGS. 1-14.

The microelectronic assemblies 100 and/or the glass cores 110 disclosed herein may be included in any suitable electronic component. FIGS. 15-18 illustrate various examples of apparatuses that may include, or be included in, any of the microelectronic assemblies 100 and/or the glass cores 110 disclosed herein.

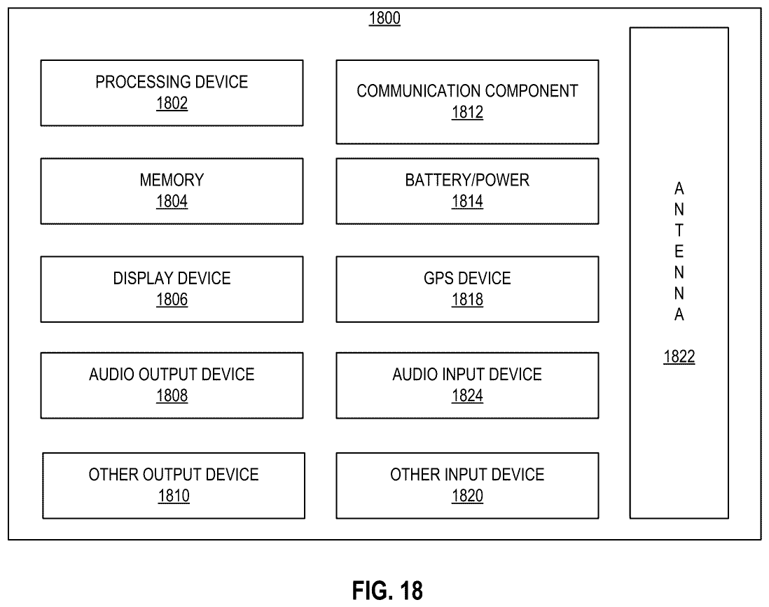

FIG. 15 is a top view of a wafer 1500 and dies 1502 that may be included in any of the microelectronic assemblies 100 as described herein. For example, a die 1502 may be any of the dies 114 described herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., some of the transistors 1640 of FIG. 16, discussed below) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 18) or other logic that is configured to store information in the memory devices or execute instructions stored in the memory array.

FIG. 16 is a side, cross-sectional view of an IC device 1600 that may be included in any of the microelectronic assemblies 100 as described herein. For example, an IC device 1600 may be provided on/in any of the dies 114 described herein. The IC device 1600 may be formed on a substrate 1602 (e.g., the wafer 1500 of FIG. 15) and may be included in a die (e.g., the die 1502 of FIG. 15). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group III-V materials (i.e., materials from groups III and V of the periodic system of elements), group II-VI (i.e., materials from groups II and IV of the periodic system of elements), or group IV materials (i.e., materials from group IV of the periodic system of elements) may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 15) or a wafer (e.g., the wafer 1500 of FIG. 15).

The IC device 1600 may include one or more device layers 1604 disposed on the substrate 1602. The device layer 1604 may include features of one or more transistors 1640 (e.g., metal oxide semiconductor field-effect transistors (MOSFETs) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 16 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 16 as interconnect layers 1606, 1608, and 1610). For example, electrically conductive features of the device layer 1604 (e.g., the gate 1622 and the S/D contacts 1624) may be electrically coupled with the interconnect structures 1628 of the interconnect layers 1606, 1608, and 1610. The one or more interconnect layers 1606, 1608, and 1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 16). Although a particular number of interconnect layers 1606, 1608, and 1610 is depicted in FIG. 16, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 16. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606, 1608, and 1610 together.

The interconnect layers 1606, 1608, and 1610 may include a dielectric material 1626 disposed between the interconnect structures 1628, as shown in FIG. 16. In some embodiments, the dielectric material 1626 disposed between the interconnect structures 1628 in different ones of the interconnect layers 1606, 1608, and 1610 may have different compositions; in other embodiments, the composition of the dielectric material 1626 between different interconnect layers 1606, 1608, and 1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606, 1608, and 1610. In FIG. 16, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606, 1608, and 1610; for example, the conductive contacts 1636 may include other analogous features (e.g., posts) that route the electrical signals to external components.

FIG. 17 is a side, cross-sectional view of an IC device assembly 1700 that may include a glass core with edge stress reduction in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the microelectronic assemblies 100 discussed above, e.g., may include one or more microelectronic assemblies 100 as discussed with reference to FIG. 1 and FIG. 2, and/or may include one or more glass cores as discussed with reference to FIGS. 3-14.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 17 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 17), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 17, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 5), an IC device (e.g., any of the IC devices described herein, or any combination of such IC devices), or any other suitable component. Generally, the package interposer 1704 may spread a connection to a wider pitch or reroute a connection to a different connection. For example, the package interposer 1704 may couple the IC package 1720 (e.g., a die) to a set of ball grid array (BGA) conductive contacts of the coupling components 1716 for coupling to the circuit board 1702. In the embodiment illustrated in FIG. 17, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a glass core with edge stress reduction, e.g., as any embodiment of the glass core 110, described herein. In some embodiments, the package interposer 1704 may be formed as a PCB. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. In any of these embodiments, the package interposer 1704 may include multiple metal layers separated from one another by layers of dielectric material and interconnected by electrically conductive vias. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 17 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 18 is a block diagram of an example communication device 1800 that may include one or more microelectronic assemblies 100 and/or one or more glass cores 110 in accordance with any of the embodiments disclosed herein. A handheld communication device or a laptop communication device may be examples of the communication device 1800. Any suitable ones of the components of the communication device 1800 may include one or more of the microelectronic assemblies 100, IC packages 1720, 1724, IC device assemblies 1700, IC devices 1600, or dies 1502 disclosed herein. In particular, any suitable ones of the components of the communication device 1800 may include one or more glass cores 110 as described herein, e.g., as a part of a microelectronic assembly 100 as described herein. A number of components are illustrated in FIG. 18 as included in the communication device 1800, but any one or more of these components may be omitted or duplicated, as suitable for the application. In some embodiments, some or all of the components included in the communication device 1800 may be attached to one or more motherboards. In some embodiments, some or all of these components are fabricated onto a single system-on-a-chip (SoC) die.

Additionally, in various embodiments, the communication device 1800 may not include one or more of the components illustrated in FIG. 18, but the communication device 1800 may include interface circuitry for coupling to the one or more components. For example, the communication device 1800 may not include a display device 1806, but may include display device interface circuitry (e.g., a connector and driver circuitry) to which a display device 1806 may be coupled. In another set of examples, the communication device 1800 may not include an audio input device 1824 or an audio output device 1808, but may include audio input or output device interface circuitry (e.g., connectors and supporting circuitry) to which an audio input device 1824 or audio output device 1808 may be coupled.

The communication device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The communication device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic RAM (STT-MRAM).

In some embodiments, the communication device 1800 may include a communication module 1812 (e.g., one or more communication modules). For example, the communication module 1812 may be configured for managing wireless communications for the transfer of data to and from the communication device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not. The communication module 1812 may be, or may include, any of the microelectronic assemblies 100 disclosed herein.

The communication module 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication module 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication module 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication module 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication module 1812 may operate in accordance with other wireless protocols in other embodiments. The communication device 1800 may include an antenna 1822 to facilitate wireless communications and/or to receive other wireless communications (such as AM or FM radio transmissions). The antenna 1822 may include one or more microelectronic assemblies 100 and/or one or more glass cores 110 as described herein, e.g., as a part of a microelectronic assembly 100 as described herein.

In some embodiments, the communication module 1812 may manage wired communications, such as electrical, optical, or any other suitable communication protocols (e.g., the Ethernet). As noted above, the communication module 1812 may include multiple communication modules. For instance, a first communication module 1812 may be dedicated to shorter-range wireless communications such as Wi-Fi or Bluetooth, and a second communication module 1812 may be dedicated to longer-range wireless communications such as global positioning system (GPS), EDGE, GPRS, CDMA, WiMAX, LTE, EV-DO, or others. In some embodiments, a first communication module 1812 may be dedicated to wireless communications, and a second communication module 1812 may be dedicated to wired communications. In some embodiments, the communication module 1812 may support millimeter wave communication.

The communication device 1800 may include battery/power circuitry 1814. The battery/power circuitry 1814 may include one or more energy storage devices (e.g., batteries or capacitors) and/or circuitry for coupling components of the communication device 1800 to an energy source separate from the communication device 1800 (e.g., AC line power).

The communication device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The communication device 1800 may include an audio output device 1808 (or corresponding interface circuitry, as discussed above). The audio output device 1808 may include any device that generates an audible indicator, such as speakers, headsets, or earbuds.

The communication device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The communication device 1800 may include a GPS device 1818 (or corresponding interface circuitry, as discussed above). The GPS device 1818 may be in communication with a satellite-based system and may receive a location of the communication device 1800, as known in the art.

The communication device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The communication device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The communication device 1800 may have any desired form factor, such as a handheld or mobile communication device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop communication device, a server or other networked computing component, a printer, a scanner, a monitor, a set-top box, an entertainment control unit, a vehicle control unit, a digital camera, a digital video recorder, or a wearable communication device. In some embodiments, the communication device 1800 may be any other electronic device that processes data.

The following paragraphs provide examples of various ones of the embodiments disclosed herein.

Example 1 provides a microelectronic assembly that includes a glass core having a bottom surface, a top surface opposite the bottom surface, and one or more sidewalls extending between the bottom surface and the top surface; and a panel of an organic material, in which the glass core is embedded within the panel.

Example 2 provides the microelectronic assembly according to example 1, further including an adhesive material between the organic material and the glass core.

Example 3 provides the microelectronic assembly according to example 2, in which the adhesive material includes an insulator material.

Example 4 provides the microelectronic assembly according to examples 2 or 3, in which the adhesive material includes a mold material.

Example 5 provides the microelectronic assembly according to any one of examples 1-4, in which the glass core is embedded within the panel by having the one or more sidewalls being enclosed by the organic material.

Example 6 provides the microelectronic assembly according to any one of examples 1-5, in which the panel protrudes with respect to the bottom surface or the top surface of the glass core.

Example 7 provides the microelectronic assembly according to any one of examples 1-6, in which the glass core is a first glass core, and the microelectronic assembly further includes one or more second glass cores embedded within the panel.

Example 8 provides the microelectronic assembly according to example 7, in which the first glass core and the one or more second glass cores are uniformly distributed within the panel.

Example 9 provides the microelectronic assembly according to any one of examples 7-8, in which the first glass core and the one or more second glass cores have substantially same shapes and dimensions.

Example 10 provides the microelectronic assembly according to example 7, in which the first glass core and at least one of the one or more second glass cores have different shapes or different dimensions.

Example 11 provides the microelectronic assembly according to any one of examples 1-10, in which an angle between a portion of a sidewall of the one or more sidewalls and one of the bottom surface or the top surface is greater than 90 degrees.

Example 12 provides the microelectronic assembly according to example 11, in which the angle is greater than 90 degrees by between about 2 and 80 degrees, e.g., by between about 5 and 60 degrees, or by between about 5 and 30 degrees.

Example 13 provides the microelectronic assembly according to any one of examples 11-12, in which: the portion of the sidewall is a first portion of the sidewall, the first portion of the sidewall contacts the bottom surface, the angle between the first portion of the sidewall and one of the bottom surface or the top surface is an angle between the first portion of the sidewall and the bottom surface, a second portion of the sidewall contacts the top surface, and an angle between the second portion of the sidewall and the top surface is greater than 90 degrees.

Example 14 provides the microelectronic assembly according to example 13, in which the angle between the first portion of the sidewall and the bottom surface and the angle between the second portion of the sidewall and the top surface are substantially equal.

Example 15 provides the microelectronic assembly according to example 13, in which the angle between the first portion of the sidewall and the bottom surface and the angle between the second portion of the sidewall and the top surface are different.

Example 16 provides the microelectronic assembly according to any one of examples 13-15, in which: a third portion of the sidewall is between the first portion and the second portion (e.g., spatially between, in a cross-section of a y-z plane), and an angle between the third portion of the sidewall and one of the bottom surface or the top surface is different from the angle between the first portion of the sidewall and the bottom surface.

Example 17 provides the microelectronic assembly according to example 16, in which the angle between the third portion of the sidewall and one of the bottom surface or the top surface is different from the angle between the second portion of the sidewall and the top surface.

Example 18 provides the microelectronic assembly according to any one of examples 11-17, further including a build-up layer on the bottom surface or the top surface of the glass core, in which the build-up layer includes a dielectric material and a conductive material arranged in the dielectric material to provide conductive pathways through the build-up layer.

Example 19 provides the microelectronic assembly according to example 18, in which the conductive material is a conductive trace or a conductive via.

Example 20 provides the microelectronic assembly according to any one of examples 18-19, in which, in a cross-sectional side view in a plane substantially perpendicular to the bottom surface or the top surface of the glass core, the sidewall of the glass core extends further out than a sidewall of the build-up layer.

Example 21 provides a microelectronic assembly that includes a glass core having a bottom surface, a top surface opposite the bottom surface, and a sidewall extending between the bottom surface and the top surface, in which an angle between a portion of the sidewall and one of the bottom surface or the top surface is greater than 90 degrees.

Example 22 provides the microelectronic assembly according to example 21, in which the angle is greater than 90 degrees by between about 2 and 80 degrees, e.g., by between about 5 and 60 degrees, or by between about 5 and 30 degrees.

Example 23 provides the microelectronic assembly according to any one of examples 21-22, in which: the portion of the sidewall is a first portion of the sidewall, the first portion of the sidewall contacts the bottom surface, the angle between the first portion of the sidewall and one of the bottom surface or the top surface is an angle between the first portion of the sidewall and the bottom surface, a second portion of the sidewall contacts the top surface, and an angle between the second portion of the sidewall and the top surface is greater than 90 degrees.

Example 24 provides the microelectronic assembly according to example 23, in which the angle between the first portion of the sidewall and the bottom surface and the angle between the second portion of the sidewall and the top surface are substantially equal.

Example 25 provides the microelectronic assembly according to example 23, in which the angle between the first portion of the sidewall and the bottom surface and the angle between the second portion of the sidewall and the top surface are different.

Example 26 provides the microelectronic assembly according to any one of examples 23-25, in which: a third portion of the sidewall is between the first portion and the second portion (e.g., spatially between, in a cross-section of a y-z plane), and an angle between the third portion of the sidewall and one of the bottom surface or the top surface is different from the angle between the first portion of the sidewall and the bottom surface.

Example 27 provides the microelectronic assembly according to example 26, in which the angle between the third portion of the sidewall and one of the bottom surface or the top surface is different from the angle between the second portion of the sidewall and the top surface.

Example 28 provides the microelectronic assembly according to any one of examples 21-27, further including a build-up layer on the bottom surface or the top surface of the glass core, in which the build-up layer includes a dielectric material and a conductive material arranged in the dielectric material to provide conductive pathways through the build-up layer.

Example 29 provides the microelectronic assembly according to example 28, in which the conductive material is a conductive trace or a conductive via.

Example 30 provides the microelectronic assembly according to any one of examples 28-29, in which, in a cross-sectional side view in a plane substantially perpendicular to the bottom surface or the top surface of the glass core, the sidewall of the glass core extends further out than a sidewall of the build-up layer.

Example 31 provides the microelectronic assembly according to any one of examples 21-30, further including a pattern of a material on the sidewall.

Example 32 provides the microelectronic assembly according to example 31, in which the material includes a metal.

Example 33 provides the microelectronic assembly according to example 31, in which the metal is copper.

Example 34 provides the microelectronic assembly according to example 31, in which the material includes a polymer.

Example 35 provides the microelectronic assembly according to example 33, in which the polymer includes a resin.

Example 36 provides the microelectronic assembly according to example 33, in which the polymer includes an epoxy.

Example 37 provides the microelectronic assembly according to any one of examples 31-36, in which the pattern includes a substantially straight line.

Example 38 provides the microelectronic assembly according to any one of examples 31-37, in which the pattern includes a curve.

Example 39 provides the microelectronic assembly according to any one of examples 31-38, in which the pattern extends from the bottom surface to the top surface.

Example 40 provides the microelectronic assembly according to any one of examples 31-38, in which the pattern is spaced apart from the bottom surface or from the top surface.

Example 41 provides the microelectronic assembly according to any one of examples 31-38, in which: the sidewall has a first portion and a second portion, the first portion of the sidewall contacts the bottom surface, the second portion of the sidewall contacts the top surface, and the pattern is on the first portion but not on the second portion.

Example 42 provides the microelectronic assembly according to example 41, in which: the sidewall further has a third portion between the first portion and the second portion (e.g., spatially between, in a cross-section of a y-z plane), and the pattern is on the third portion.

Example 43 provides the microelectronic assembly according to example 42, in which the material of the pattern on the first portion is materially continuous with the material of the pattern on the third portion.

Example 44 provides the microelectronic assembly according to example 42, in which the material of the pattern on the first portion is materially discontinuous with (i.e., spaced apart from) the material of the pattern on the third portion.

Example 45 provides the microelectronic assembly according to any one of examples 31-38, in which: the sidewall has a first portion and a second portion, the first portion of the sidewall contacts the bottom surface, the second portion of the sidewall contacts the top surface, and the pattern is on the second portion but not on the first portion.

Example 46 provides the microelectronic assembly according to example 45, in which: the sidewall further has a third portion between the first portion and the second portion (e.g., spatially between, in a cross-section of a y-z plane), and the pattern is on the third portion.

Example 47 provides the microelectronic assembly according to example 46, in which the material of the pattern on the second portion is materially continuous with the material of the pattern on the third portion.

Example 48 provides the microelectronic assembly according to example 46, in which the material of the pattern on the second portion is materially discontinuous with (i.e., spaced apart from) the material of the pattern on the third portion.

Example 49 provides the microelectronic assembly according to any one of examples 31-38, in which: the sidewall has a first portion, a second portion, and a third portion, the first portion of the sidewall contacts the bottom surface, the second portion of the sidewall contacts the top surface, the third portion is between the first portion and the second portion (e.g., spatially between, in a cross-section of a y-z plane), the pattern is on the first portion, on the second portion, and on the third portion.

Example 50 provides the microelectronic assembly according to example 49, in which the material of the pattern on the third portion is materially continuous with the material of the pattern on the first portion and is materially continuous with the material of the pattern on the second portion.

Example 51 provides the microelectronic assembly according to example 49, in which the material of the pattern on the third portion is materially continuous with the material of the pattern on the first portion and is materially discontinuous with the material of the pattern on the second portion.

Example 52 provides the microelectronic assembly according to example 49, in which the material of the pattern on the third portion is materially continuous with the material of the pattern on the second portion and is materially discontinuous with the material of the pattern on the first portion.

Example 53 provides the microelectronic assembly according to any one of examples 31-52, in which: the sidewall is a first sidewall, the pattern is a first pattern, the glass core further includes a second sidewall, and the microelectronic assembly further includes a second pattern of the material on the second sidewall.

Example 54 provides the microelectronic assembly according to example 53, in which the second sidewall is opposite the first sidewall.

Example 55 provides the microelectronic assembly according to example 53, in which the second sidewall is adjacent to the first sidewall.

Example 56 provides the microelectronic assembly according to any one of examples 31-52, in which: the glass core has a first sidewall, a second sidewall, a third sidewall, and a fourth sidewall, the sidewall is the first sidewall, the pattern is absent on the second sidewall and the third sidewall.

Example 57 provides the microelectronic assembly according to example 56, in which the second sidewall is opposite the third sidewall.

Example 58 provides the microelectronic assembly according to example 56, in which the second sidewall is adjacent to the third sidewall.

Example 59 provides the microelectronic assembly according to any one of examples 56-58, in which the pattern is absent on the fourth sidewall.

Example 60 provides the microelectronic assembly according to any one of examples 31-59, in which the pattern is in a recess or an opening in the sidewall.

Example 61 provides a microelectronic assembly that includes a glass core having a bottom surface, a top surface opposite the bottom surface, and a sidewall extending between the bottom surface and the top surface; and a pattern of a material on the sidewall.

Example 62 provides the microelectronic assembly according to example 61, in which the material includes a metal.

Example 63 provides the microelectronic assembly according to example 61, in which the metal is copper.

Example 64 provides the microelectronic assembly according to example 61, in which the material includes a polymer.

Example 65 provides the microelectronic assembly according to example 63, in which the polymer includes a resin.

Example 66 provides the microelectronic assembly according to example 63, in which the polymer includes an epoxy.

Example 67 provides the microelectronic assembly according to any one of examples 61-66, in which the pattern includes a substantially straight line.

Example 68 provides the microelectronic assembly according to any one of examples 61-67, in which the pattern includes a curve.

Example 69 provides the microelectronic assembly according to any one of examples 61-68, in which the pattern extends from the bottom surface to the top surface.

Example 70 provides the microelectronic assembly according to any one of examples 61-68, in which the pattern is spaced apart from the bottom surface or from the top surface.

Example 71 provides the microelectronic assembly according to any one of examples 61-68, in which: the sidewall has a first portion and a second portion, the first portion of the sidewall contacts the bottom surface, the second portion of the sidewall contacts the top surface, and the pattern is on the first portion but not on the second portion.

Example 72 provides the microelectronic assembly according to example 71, in which: the sidewall further has a third portion between the first portion and the second portion (e.g., spatially between, in a cross-section of a y-z plane), and the pattern is on the third portion.

Example 73 provides the microelectronic assembly according to example 72, in which the material of the pattern on the first portion is materially continuous with the material of the pattern on the third portion.

Example 74 provides the microelectronic assembly according to example 72, in which the material of the pattern on the first portion is materially discontinuous with (i.e., spaced apart from) the material of the pattern on the third portion.

Example 75 provides the microelectronic assembly according to any one of examples 61-68, in which: the sidewall has a first portion and a second portion, the first portion of the sidewall contacts the bottom surface, the second portion of the sidewall contacts the top surface, and the pattern is on the second portion but not on the first portion.

Example 76 provides the microelectronic assembly according to example 75, in which: the sidewall further has a third portion between the first portion and the second portion (e.g., spatially between, in a cross-section of a y-z plane), and the pattern is on the third portion.

Example 77 provides the microelectronic assembly according to example 76, in which the material of the pattern on the second portion is materially continuous with the material of the pattern on the third portion.

Example 78 provides the microelectronic assembly according to example 76, in which the material of the pattern on the second portion is materially discontinuous with (i.e., spaced apart from) the material of the pattern on the third portion.

Example 79 provides the microelectronic assembly according to any one of examples 61-68, in which: the sidewall has a first portion, a second portion, and a third portion, the first portion of the sidewall contacts the bottom surface, the second portion of the sidewall contacts the top surface, the third portion is between the first portion and the second portion (e.g., spatially between, in a cross-section of a y-z plane), the pattern is on the first portion, on the second portion, and on the third portion.

Example 80 provides the microelectronic assembly according to example 79, in which the material of the pattern on the third portion is materially continuous with the material of the pattern on the first portion and is materially continuous with the material of the pattern on the second portion.

Example 81 provides the microelectronic assembly according to example 79, in which the material of the pattern on the third portion is materially continuous with the material of the pattern on the first portion and is materially discontinuous with the material of the pattern on the second portion.

Example 82 provides the microelectronic assembly according to example 79, in which the material of the pattern on the third portion is materially continuous with the material of the pattern on the second portion and is materially discontinuous with the material of the pattern on the first portion.

Example 83 provides the microelectronic assembly according to any one of examples 61-82, in which: the sidewall is a first sidewall, the pattern is a first pattern, the glass core further includes a second sidewall, and the microelectronic assembly further includes a second pattern of the material on the second sidewall.

Example 84 provides the microelectronic assembly according to example 83, in which the second sidewall is opposite the first sidewall.

Example 85 provides the microelectronic assembly according to example 83, in which the second sidewall is adjacent to the first sidewall.

Example 86 provides the microelectronic assembly according to any one of examples 61-82, in which: the glass core has a first sidewall, a second sidewall, a third sidewall, and a fourth sidewall, the sidewall is the first sidewall, the pattern is absent on the second sidewall and the third sidewall.

Example 87 provides the microelectronic assembly according to example 86, in which the second sidewall is opposite the third sidewall.

Example 88 provides the microelectronic assembly according to example 86, in which the second sidewall is adjacent to the third sidewall.

Example 89 provides the microelectronic assembly according to any one of examples 86-88, in which the pattern is absent on the fourth sidewall.

Example 90 provides the microelectronic assembly according to any one of examples 61-89, in which the pattern is in a recess or an opening in the sidewall.

Example 91 provides the microelectronic assembly according to any one of examples 61-90, in which an angle between a portion of the sidewall and one of the bottom surface or the top surface is greater than 90 degrees.

Example 92 provides the microelectronic assembly according to example 91, in which the angle is greater than 90 degrees by between about 2 and 80 degrees, e.g., by between about 5 and 60 degrees, or by between about 5 and 30 degrees.

Example 93 provides the microelectronic assembly according to any one of examples 91-92, in which: the portion of the sidewall is a first portion of the sidewall, the first portion of the sidewall contacts the bottom surface, the angle between the first portion of the sidewall and one of the bottom surface or the top surface is an angle between the first portion of the sidewall and the bottom surface, a second portion of the sidewall contacts the top surface, and an angle between the second portion of the sidewall and the top surface is greater than 90 degrees.

Example 94 provides the microelectronic assembly according to example 93, in which the angle between the first portion of the sidewall and the bottom surface and the angle between the second portion of the sidewall and the top surface are substantially equal.

Example 95 provides the microelectronic assembly according to example 93, in which the angle between the first portion of the sidewall and the bottom surface and the angle between the second portion of the sidewall and the top surface are different.

Example 96 provides the microelectronic assembly according to any one of examples 93-95, in which: a third portion of the sidewall is between the first portion and the second portion (e.g., spatially between, in a cross-section of a y-z plane), and an angle between the third portion of the sidewall and one of the bottom surface or the top surface is different from the angle between the first portion of the sidewall and the bottom surface.

Example 97 provides the microelectronic assembly according to example 96, in which the angle between the third portion of the sidewall and one of the bottom surface or the top surface is different from the angle between the second portion of the sidewall and the top surface.

Example 98 provides the microelectronic assembly according to any one of examples 91-97, further including a build-up layer on the bottom surface or the top surface of the glass core, in which the build-up layer includes a dielectric material and a conductive material arranged in the dielectric material to provide conductive pathways through the build-up layer.

Example 99 provides the microelectronic assembly according to example 98, in which the conductive material is a conductive trace or a conductive via.

Example 100 provides the microelectronic assembly according to any one of examples 98-99, in which, in a cross-sectional side view in a plane substantially perpendicular to the bottom surface or the top surface of the glass core, the sidewall of the glass core extends further out than a sidewall of the build-up layer.

Example 101 provides a microelectronic assembly that includes a glass core having a bottom surface, a top surface opposite the bottom surface, and a sidewall extending between the bottom surface and the top surface, in which, in a top-down plane view, at least one corner of the sidewall is rounded or flattened.

Example 102 provides the microelectronic assembly according to example 101, in which, in the top-down plane view, an angle between a first portion of the sidewall and a second portion of the sidewall, adjacent to the first portion of the sidewall, is greater than 90 degrees but less than 180 degrees.

Example 103 provides the microelectronic assembly according to any one of the preceding examples, further including a component coupled to the glass core, in which the component is one of an IC die, a package substrate, or a redistribution layer

Example 104 provides the microelectronic assembly according to any one of the preceding examples, in which the glass core is a solid layer of glass.

Example 105 provides the microelectronic assembly according to any one of the preceding examples, in which a cross-section of the glass core in a plane perpendicular to a surface of the component is substantially rectangular.

Example 106 provides the microelectronic assembly according to any one of the preceding examples, in which a cross-section of the glass core in a plane parallel to a surface of the component is substantially rectangular.

Example 107 provides the microelectronic assembly according to any one of the preceding examples, in which the glass core is a layer of glass including at least 23% silicon by weight.

Example 108 provides the microelectronic assembly according to any one of the preceding examples, in which the glass core is a layer of glass including at least 26% oxygen by weight.

Example 109 provides the microelectronic assembly according to any one of the preceding examples, in which the glass core is a layer of glass including at least 23% silicon by weight and at least 26% oxygen by weight.

Example 110 provides the microelectronic assembly according to any one of the preceding examples, in which the glass core is a layer of glass including at least 5% aluminum by weight.

Example 111 provides the microelectronic assembly according to any one of the preceding examples, in which the glass core is a layer of glass that does not include an organic adhesive or an organic material.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic assembly, comprising:
a glass core having a bottom surface, a top surface opposite the bottom surface, and one or more sidewalls between the bottom surface and the top surface; and
a panel of an organic material, wherein the glass core is embedded within the panel.

2. The microelectronic assembly according to claim 1, further comprising an adhesive material between the organic material and the glass core.

3. The microelectronic assembly according to claim 1, wherein the glass core is embedded within the panel by having the one or more sidewalls enclosed by the organic material.

4. The microelectronic assembly according to claim 1, wherein the panel protrudes with respect to the bottom surface or the top surface of the glass core.

5. The microelectronic assembly according to claim 1, wherein the glass core is a first glass core, and the microelectronic assembly further includes one or more second glass cores embedded within the panel.

6. The microelectronic assembly according to claim 5, wherein the first glass core and the one or more second glass cores are uniformly distributed within the panel.

7. The microelectronic assembly according to claim 5, wherein the first glass core and at least one of the one or more second glass cores have different shapes or different dimensions.

8. The microelectronic assembly according to claim 1, wherein an angle between a portion of a sidewall of the one or more sidewalls and one of the bottom surface or the top surface is greater than 90 degrees.

9. A microelectronic assembly, comprising:
a glass core having a bottom surface, a top surface opposite the bottom surface, and a sidewall between the bottom surface and the top surface,
wherein an angle between a portion of the sidewall and one of the bottom surface or the top surface is greater than 90 degrees.

10. The microelectronic assembly according to claim 9, wherein the angle is greater than 90 degrees by between about 2 and 80 degrees.

11. The microelectronic assembly according to claim 9, wherein:
the portion of the sidewall is a first portion of the sidewall,
the first portion of the sidewall contacts the bottom surface,
the angle between the first portion of the sidewall and one of the bottom surface or the top surface is an angle between the first portion of the sidewall and the bottom surface,
a second portion of the sidewall contacts the top surface, and
an angle between the second portion of the sidewall and the top surface is greater than 90 degrees.

12. The microelectronic assembly according to claim 11, wherein:
a third portion of the sidewall is between the first portion and the second portion, and
an angle between the third portion of the sidewall and one of the bottom surface or the top surface is different from the angle between the first portion of the sidewall and the bottom surface.

13. The microelectronic assembly according to claim 12, wherein the angle between the third portion of the sidewall and one of the bottom surface or the top surface is different from the angle between the second portion of the sidewall and the top surface.

14. The microelectronic assembly according to claim 9, further comprising:
a build-up layer on the bottom surface or the top surface of the glass core,
wherein the build-up layer includes a dielectric material and a conductive material in the dielectric material.

15. The microelectronic assembly according to claim 14, wherein the conductive material is a conductive trace or a conductive via.

16. The microelectronic assembly according to claim 14, wherein, in a cross-sectional side view in a plane substantially perpendicular to the bottom surface or the top surface of the glass core, the sidewall of the glass core extends further out than a sidewall of the build-up layer.

17. The microelectronic assembly according to claim 9, further comprising a pattern of a material on the sidewall, wherein the material includes a metal.

18. The microelectronic assembly according to claim 9, further comprising a pattern of a material on the sidewall, wherein the material includes a polymer.

19. A microelectronic assembly, comprising:
a glass core having a bottom surface, a top surface opposite the bottom surface, and a sidewall between the bottom surface and the top surface; and
a pattern of a material on the sidewall, wherein the material includes a metal or a polymer.

20. The microelectronic assembly according to claim 19, wherein the pattern extends from the bottom surface to the top surface.
